(19) United States
(12) Patent Application Publication
(10) Pub. No.: US 2026/0333691 A1
(43) Pub. Date: Oct. 22, 2026

(54) MEMORY DEVICE INCLUDING CONTROL GATES HAVING CONDUCTIVE MATERIALS AND DIELECTRIC LINERS

(71) Applicant: Micron Technology, Inc., Boise, ID (US)

(72) Inventors: Timothy Kurnia Hardiman, Singapore (SG); Bhavesh Bhartia, Singapore (SG); Patrict M. Flynn, Boise, ID (US); Jian Yong Sim, Singapore (SG)

(21) Appl. No.: 19/186,027

(22) Filed: Apr. 22, 2025

(51) Int. Cl. H10B 43/27; G11C 16/04; H10B 41/10; H10B 41/27; H10B 41/35; H10B 41/40; H10B 43/10; H10B 43/35; H10B 43/40; H10D 30/01; H10D 30/68; H10D 30/69; H10D 62/83; H10D 64/01; H10D 64/66; H10D 64/68

(52) U.S. Cl. CPC H10B 43/27; G11C 16/0483; H10B 41/10; H10B 41/27; H10B 41/35; H10B 41/40; H10B 43/10; H10B 43/35; H10B 43/40; H10D 30/0411; H10D 30/0413; H10D 30/689; H10D 30/693; H10D 62/83; H10D 64/037; H10D 64/665; H10D 64/691

(57) ABSTRACT

Some embodiments include apparatuses and methods of forming the apparatuses. One of the apparatuses includes a dielectric liner including a first dielectric portion between a level of conductive material and a first level of dielectric material and, and a second dielectric portion between the level of conductive material and a second level of dielectric material; a memory cell pillar extending through the first level of dielectric material and the second level of dielectric material; and a dielectric structure adjacent the first level of dielectric material, the second level of dielectric material, and the dielectric liner. The first dielectric portion includes first and second edges adjacent the dielectric structure. The level of conductive material includes a third edge adjacent the dielectric structure. The third edge is closer to the memory cell pillar than each of the first edge and the second edge.

### BACKGROUND

Memory devices are widely used in computers and many other electronic items. A memory device has numerous memory cells used to store information (e.g., data) and conductive control gates to control access to the memory cells during operations of the memory device. In some conventional memory devices, the control gates are located one over another (e.g., stacked one over another) and are separated from each other respectively by levels of dielectric materials that are interleaved with the control gates. Such conventional memory devices also include a dielectric structure adjacent the control gates and levels of dielectric materials. In some of such conventional memory devices, the regions adjacent the dielectric structure, the control gates, and levels of dielectric materials can be susceptible to structural damage. The structural damage can be caused by breakdown in the levels of dielectric material between adjacent control gates, or a short between control gates, or both. The structural damage leads to reduced yield or inferior device performance, or both.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having memory cell strings and associated select circuits, according to some embodiments described herein.

FIG. 3 shows a detailed schematic diagram of the memory device of FIG. 2, according to some embodiments described herein.

FIG. 4A shows a side view (e.g., cross-section) of a structure of a portion of the memory device of FIG. 3 including memory cell strings having pillars extending through control gates in two blocks of memory cells, and a dielectric structure between the two blocks, according to some embodiments described herein.

FIG. 4B shows a cross-section of portion of a pillar and a portion of a control gate of the memory device of FIG. 4A, according to some embodiments described herein.

FIG. 4C shows a top view of a portion of the memory device of FIG. 4A including relative locations of the blocks, dielectric structures, the pillars of memory cell strings, and the data lines of the memory device, according to some embodiments described herein.

FIG. 4D shows a side view (e.g., cross-section) taken along line 4D-4D of FIG. 4C including a side view of a dielectric structure of the memory device of FIG. 4C, according to some embodiments described herein.

FIG. 4E shows a side view (e.g., cross-section) taken along line 4E-4E of FIG. 4C including a side view of a dielectric structure and memory cell pillars of the memory device of FIG. 4C, according to some embodiments described herein.

FIG. 5 shows a memory device that can be a variation of the memory device of FIG. 4E including a variation of a dielectric liner, according to some embodiments described herein.

FIG. 6A and FIG. 6B through FIG. 15A and FIG. 15B, and FIG. 16A through FIG. 18B show different views of elements during processes of forming a memory device, according to some embodiments described herein.

FIG. 15C, FIG. 15D, FIG. 19, and FIG. 20 show different views of elements during alternative processes of forming a memory device, according to some embodiments described herein.

### DETAILED DESCRIPTION

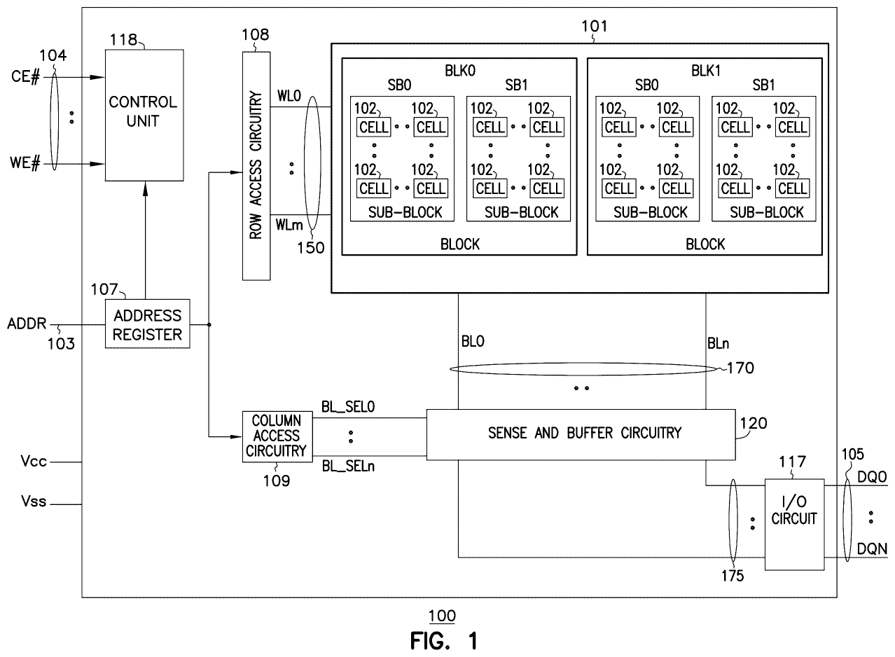

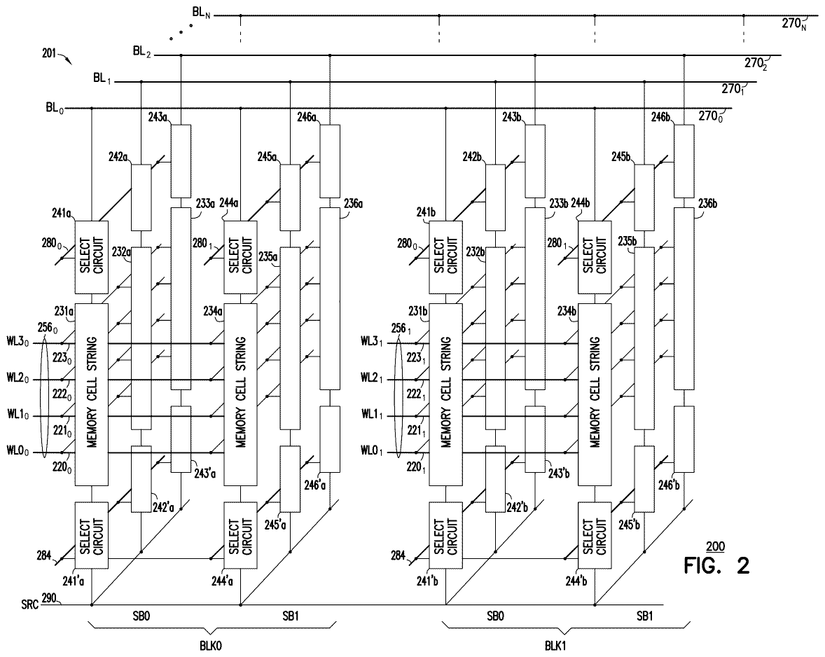

The techniques described herein involve a memory device that includes levels (e.g., layers) of control gates, levels of dielectric materials interleaved with the levels control gates, and a dielectric structure adjacent the levels of control gates and the levels of dielectric materials. The control gates include respective levels of conductive materials and respective dielectric liners between the levels of conductive materials and adjacent levels of dielectric materials. The levels of conductive materials and the dielectric liners adjacent the dielectric structure have certain dimensions to mitigate structural damage that may occur at the regions adjacent levels of conductive materials and the dielectric liners. This can lead to improve yield and device performance. Other improvements and benefits of the techniques described herein are further discussed below with reference to FIG. 1 through FIG. 20.

FIG. 1 shows a block diagram of an apparatus in the form of a memory device 100, according to some embodiments described herein. Memory device 100 can include a memory array 101 (or multiple memory arrays) containing memory cells 102 arranged in blocks (blocks of memory cells), such as blocks BLK0 and BLK1. Each of blocks BLK0 and BLK1 can include its own sub-blocks, such as sub-blocks SB0 and SB1. In the physical structure of memory device 100, memory cells 102 can be arranged vertically (e.g., stacked over each other) over a substrate (e.g., a semiconductor substrate) of memory device 100. FIG. 1 shows memory device 100 having two blocks BLK0 and BLK1 and two sub-blocks in each of the blocks as an example. Memory device 100 can have more than two blocks and more than two sub-blocks in each of the blocks.

As shown in FIG. 1, memory device 100 can include access lines 150 (which can include word lines) and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 and BLK1 and data lines 170 to selectively exchange information (e.g., data) with memory cells 102 of blocks BLK0 and BLK1. Block BLK0 can have access lines (e.g., word lines) that are separated (electrically separated) from access lines (e.g., word lines) of block BLK1. Sub-blocks of the same block can share access lines (e.g., can share word lines) and can be controlled by the same access lines. For example, sub-blocks SB0 and SB1 of block BLK0 can share a group of access lines associated with block BLK0, and sub-blocks SB0 and SB1 of block BLK1 can share another group of access lines associated with block BLK1.

Memory device 100 can include an address register 107 to receive address information ADDR (e.g., address signals) on lines 103 (e.g., address lines). Memory device 100 can include row access circuitry 108 and column access circuitry 109 that can decode address information from address register 107. Based on decoded address information, memory device 100 can determine which memory cells 102 of which sub-blocks of blocks BLK0 and BLK1 are to be accessed during a memory operation. Memory device 100 can perform a read operation to read (e.g., sense) information (e.g., previously stored information) from memory cells 102 of blocks BLK0 and BLK1, or a write (e.g., programming) operation to store (e.g., program) information in memory cells 102 of blocks BLK0 and BLK1. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 and BLK1.

Memory device 100 can include a control unit 118 that can be configured to control memory operations of memory device 100 based on control signals on lines 104. Examples of the control signals on lines 104 include one or more clock signals and other signals (e.g., a chip enable signal CE#, a write enable signal WE#) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 and BLK1 and provide the value of the information to lines 175 (e.g., global data lines). Sense and buffer circuitry 120 can also be configured to use signals on lines 175 to determine the value of information to be stored (e.g., programmed) in memory cells 102 of blocks BLK0 and BLK1 (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 and BLK1 and lines 105 (e.g., I/O lines). Signals DQ0 through DQN on lines 105 can represent information read from or stored in memory cells 102 of blocks BLK0 and BLK1. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 20.

FIG. 2 shows a general schematic diagram of a portion of a memory device 200 including a memory array 201 having memory cell strings and associated select circuits, according to some embodiments described herein. Memory device 200 can correspond to memory device 100 of FIG. 1. For example, memory array 201 can form part of memory array 101 of FIG. 1.

As shown in FIG. 2, memory device 200 can include blocks (blocks of memory cells) BLK0 and BLK1. Two blocks are shown as an example. Memory device 200 can include many blocks (e.g., up to thousands or more blocks). In the physical structure of memory device 200, the blocks can be arranged (e.g., formed) one block next to another block, such that each block can have a neighboring block. Neighboring blocks are blocks located immediately next to (e.g., adjacent) each other. For example, in the physical structure of memory device 200, blocks BLK0 and BLK1 can be neighboring blocks.

Each of blocks BLK0 and BLK1 of memory device 200 can include (e.g., can be divided into) sub-blocks. For example, each of blocks BLK0 and BLK1 can include sub-blocks SB0 and SB1. Blocks BLK0 and BLK1 can include the same number of sub-blocks. FIG. 2 shows an example where each of blocks BLK0 and BLK1 can include two sub-blocks (e.g., SB0 and SB1). However, each of blocks BLK0 and BLK1 can have more than two blocks (e.g., four sub-blocks SB0, SB1, SB2, and SB3 or more than four sub-blocks).

As shown in FIG. 2, each sub-block (e.g., SB0 or SB1) has its own memory cell strings that can be associated with (e.g., coupled to) respective select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SB1 of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SB1 of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively. The sub-blocks of the blocks (e.g., blocks BLK0 and BLK1) of memory device 200 can have the same number of memory cell strings and associated select circuits.

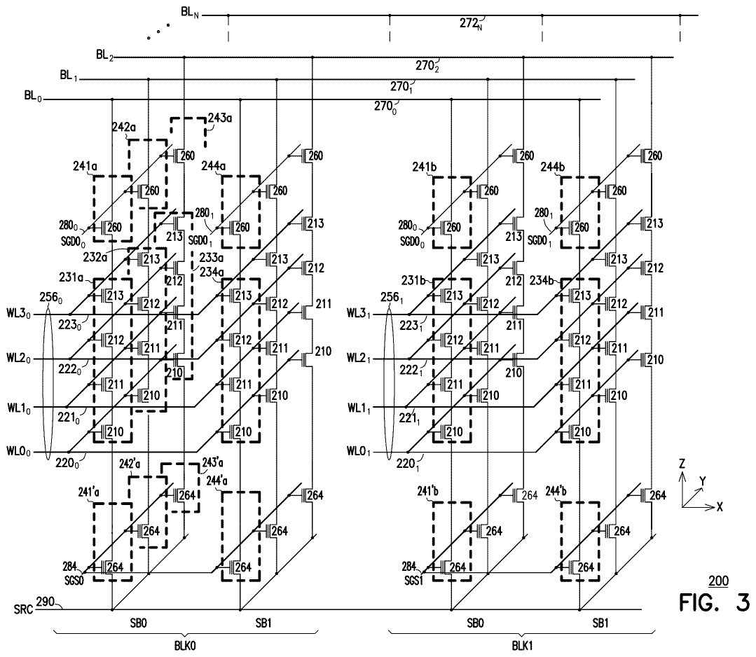

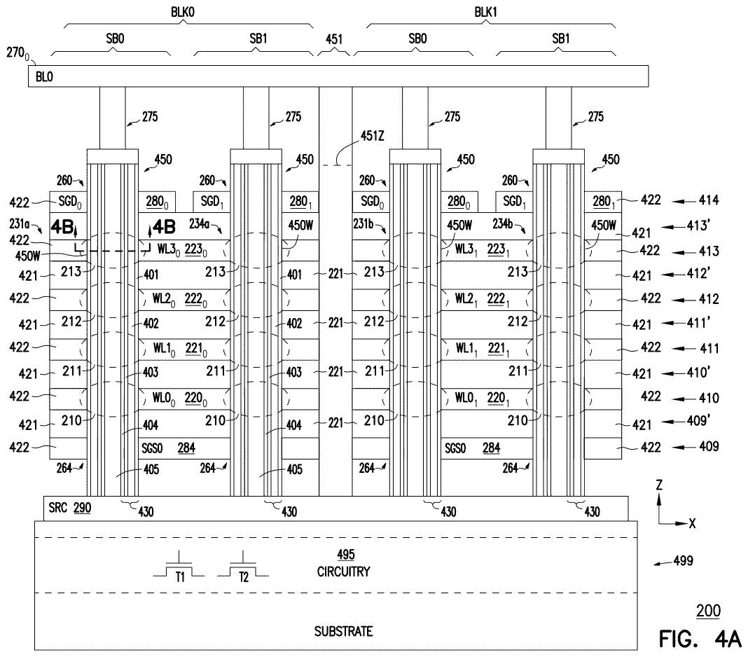

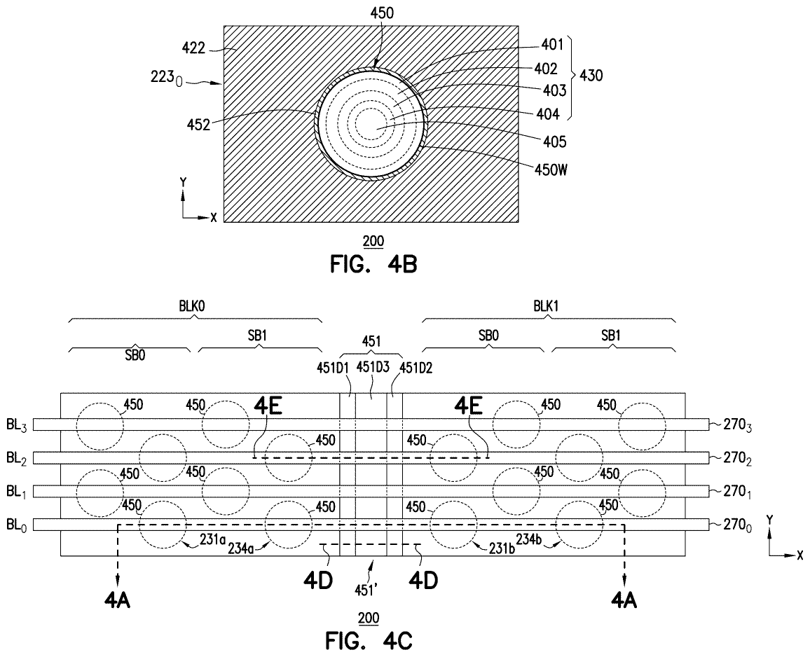

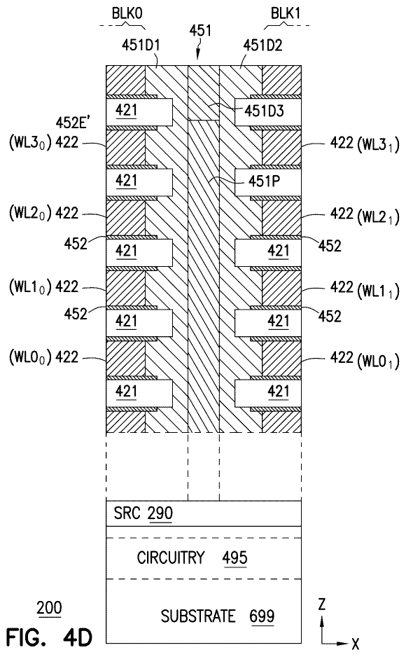

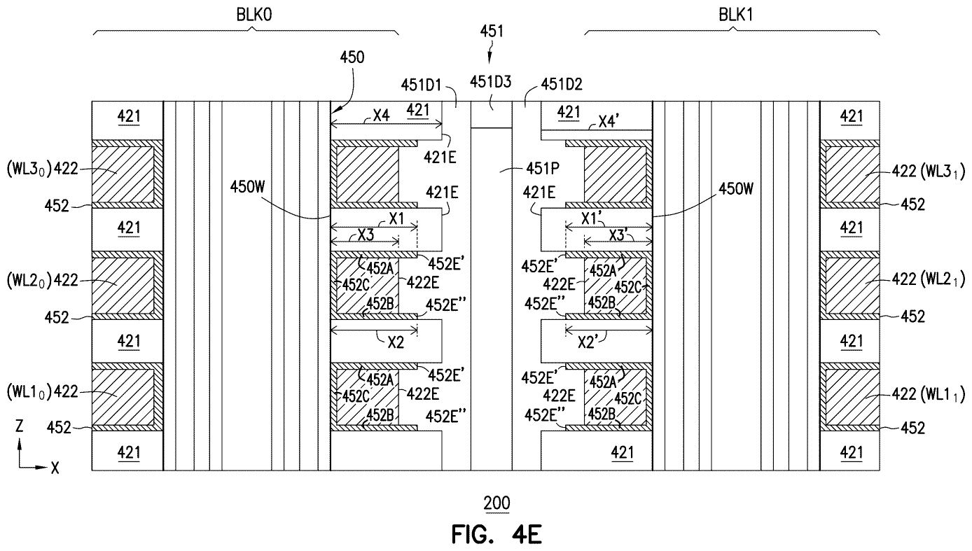

FIG. 2 shows an example of three memory cell strings and their associated circuits in a sub-block (e.g., in sub-block SB0). The number of memory cell strings and their associated select circuits in each of the sub-blocks of blocks BLK0 and BLK1 can vary. Each of the memory cell strings of memory device 200 can include series-connected memory cells (shown in detail in FIG. 3 and FIG. 4A) and a memory cell pillar (e.g., pillar 450 in FIG. 4A) associated with the series-connected memory cells. The series-connected memory cells can be located (e.g., vertically located) along a respective portion of the pillar.

As shown in FIG. 2, memory device 200 can include data lines 270₀through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 and BLK1 can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be common source (e.g., common source plate or common source region) of blocks BLK0 and BLK1. Alternatively, each of blocks BLK0 and BLK1 can have its own source similar to source 290. Source 290 can be coupled to a ground connection of memory device 200.

Memory device 200 can include control gates (e.g., word lines) 220₀, 221₀, 222₀, and 223₀ in block BLK0 that can be part of conductive paths (e.g., access lines) 256₀ of memory device 200 (that can correspond to part of access lines 150 of memory device 100 of FIG. 1). Memory device 200 can include control gates (e.g., word lines) 220₁, 221₁, 222₁, and 223₁ in block BLK1 that can be part of other conductive paths (e.g., access lines) of memory device 200 (that can correspond to part of access lines 150 of memory device 100 of FIG. 1). Control gates 220₀, 221₀, 222₀, and 223₀ are separated (electrically separated) from each other. Control gates 220₁, 221₁, 222₁, and 223₁ are separated (electrically separated) from each other. Control gates 220₀, 221₀, 222₀, and 223₀ are separated (electrically separated) from control gates 220₁, 221₁, 222₁, and 223₁. Thus, blocks BLK0 and BLK1 can be accessed separately (e.g., accessed one at a time). For example, block BLK0 can be accessed at one time using control gates 220₀, 221₀, 222₀, and 223₀, and block BLK1 can be accessed at another time using control gates 220₁, 221₁, 222₁, and 223₁.

Memory device 200 can have the same number of control gates among the blocks (e.g., blocks BLK0 and BLK1) of memory device 200. In the example of FIG. 2, memory device 200 has four control gates in each of blocks BLK0 and BLK1. The number of control gates in the blocks (e.g., blocks BLK0 and BLK1) of memory device 200 can be different from four. For example, each of blocks BLK0 and BLK1 can include up to (or more than) hundred control gates.

Each of control gates 220₀, 221₀, 222₀, and 223₀ can be part of a structure (e.g., a level) of conductive material (e.g., conductive material 422 in FIG. 4A and FIG. 4E) located in a respective level (physical level) of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation). For example, during a read operation, memory device 200 can use signals WL0₀, WL1₀, WL2₀, and WL3₀ to control access to selected memory cells of block BLK0 to read (e.g., sense) information (e.g., previously stored information) from the memory cells of block BLK0. In another example, during a write operation, memory device 200 can use signals WL0₀, WL1₀, WL2₀, and WL3₀ to control access to selected memory cells of block BLK0 to store information in the selected memory cell of block BLK0.

Each of control gates 220₁, 221₁, 222₁, and 223₁ can be part of a structure (e.g., a level) of conductive material (e.g., conductive material 422 in FIG. 4A and FIG. 4E) located in a respective level (physical level) of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation). For example, during a read operation, memory device 200 can use signals WL0₁, WL1₁, WL2₁, and WL3₁ to control access to selected memory cells of block BLK1 to read (e.g., sense) information (e.g., previously stored information) from the memory cells of block BLK1. In another example, during a write operation, memory device 200 can use signals WL0₁, WL1₁, WL2₁, and WL3₁ to control access to selected memory cells of block BLK1 to store information in the selected memory cell of block BLK1.

As shown in FIG. 2, in sub-block SB0 of block BLK0, memory device 200 includes a select line 280₀ (e.g., drain select line) that can be shared by select circuits 241a, 242a, and 243a. In sub-block SB1 of block BLK0, memory device 200 includes a select line 280₁ (e.g., drain select line) that can be shared by select circuits 244a, 245a, and 246a. Block BLK0 can include a select line 284 (e.g., source select line) that can be shared by select circuits 241′a, 242′a, 243′a, 244′a, 245′a, and 246′a.

In sub-block SB0 of block BLK1, memory device 200 includes a select line 280₀ (e.g., drain select line) that can be shared by select circuits 241b, 242b, and 243b. Select line 280₀ of block BLK0 is separated (electrically separated) from select line 280₀ of block BLK1. In sub-block SB1 of block BLK1, memory device 200 includes a select line 280₁ (e.g., drain select line) that can be shared by select circuits 244b, 245b, and 246b. Select line 280₁ of block BLK0 is separated (electrically separated) from select line 280₁ of block BLK1. Block BLK1 can include a select line 284 (e.g., source select line) that can be shared by select circuits 241′b, 242′b, 243′b, 244′b, 245′b, and 246′b.

FIG. 2 shows an example where memory device 200 includes one drain select line (e.g., select line 280₀ or 280₁) associated with a drain select circuit (e.g., select circuits 241a, 242a, or 243a) in a sub-block (e.g., sub-block SB0 of block BLK0). However, memory device 200 can include multiple drain select lines associated with a drain select circuit.

FIG. 2 shows an example where memory device 200 includes one source select line (e.g., select line 284) associated with a source select circuit (e.g., select circuits 241′a, 242′a, or 243′a) in a sub-block (e.g., sub-block SB0 of block BLK0). However, memory device 200 can include more than one source select line associated with a source select circuit.

Each of the drain select circuits of memory device 200 can include a drain select gate (e.g., drain select gate or transistor 260 in FIG. 3) coupled between a respective data line and a respective memory cell string. The drain select gate can be controlled (e.g., turned on or turned off) by the drain select line based on a voltage provided to the signal on the drain select line.

Each of the source select circuits of memory device 200 can include a select gate (e.g., a source select gate or transistor 264 shown in FIG. 3) coupled between source 290 and a respective memory cell string. The source select gate can be controlled (e.g., turned on or turned off) by the source select line based on a voltage provided to the signal on the source select line.

In FIG. 2, each of the memory cell strings of memory device 200 has memory cells (shown in FIG. 3) arranged in a string (e.g., coupled in series among each other) to store information. During an operation (e.g., read, write, or erase operation) of memory device 200, the memory cell strings can be individually selected to access the memory cells in the selected memory cell string in order to store information in or read information from the selected memory cell string. One or both select circuits (a drain select circuit and a source select circuit) associated with a selected memory cell string can be activated (e.g., by turning on the select gate (e.g., transistor) in the select circuit (or selected circuits)), depending on which operation memory device 200 performs on the selected memory cell string.

Activating a particular select circuit among the select circuits of memory device 200 during an operation of memory device 200 can include providing (e.g., applying) a voltage having a certain value to the signal on the select line associated with that particular select circuit. When a particular drain select circuit of memory device 200 is activated, it can electrically connect (e.g., form a current path from) a selected memory cell string associated with that particular select circuit to a respective data line (e.g., one of data lines 270₀ through 270_{N}). When a particular source select circuit is activated, it can electrically connect (e.g., form a current path from) a selected memory cell string associated with that particular select circuit to source 290.

FIG. 3 shows a detailed schematic diagram of memory device 200 of FIG. 2, according to some embodiments described herein. For simplicity, only some of the memory cell strings and some of the select circuits of memory device 200 of FIG. 2 are labeled in FIG. 3. The X, Y, and Z directions in FIG. 3 can be relative to the physical directions (e.g., dimensions) of the structure of memory device 200. For example, the Z-direction can be a direction perpendicular to (e.g., vertical direction with respect to) a substrate of memory device 200 (e.g., a substrate 499 shown in FIG. 4A). The Z-direction is perpendicular to the X-direction and Y-direction (e.g., the Z-direction is perpendicular to an X-Y plane of memory device 200).

As shown in FIG. 3, each select line can carry an associated select signal. For example, in sub-block SB0 of block BLK0, select line (e.g., drain select line) 280₀ can carry an associated signal (e.g., drain select-gate signal) SGD0₀. In sub-block SB1 of block BLK0, select line (e.g., drain select line) 280₁ can carry an associated signals SGD0₁. Sub-blocks SB0 and SB1 of block BLK0 can share select line 284 and associated signal (e.g., source select-gate signal) SGS0 of block BLK0.

In sub-block SB0 of block BLK1, select line 280₀ (e.g., drain select line) can carry an associated signal SGD0₀. In sub-block SB1 of block BLK1, select line 280₁ (e.g., drain select line) can carry an associated signal SGD0₁. Sub-blocks SB0 and SB1 of block BLK1 can share select line 284 and associated signal (e.g., source select-gate signal) SGS1 of block BLK1.

As shown in FIG. 3, memory device 200 can include memory cells 210, 211, 212, and 213; select gates 260 (e.g., drain select gates or transistors); and select gates 264 (e.g., source select gates or transistors) that can be physically arranged in three dimensions (3D), such as X, Y, and Z directions (e.g., dimensions), with respect to the structure (shown in FIG. 4A) of memory device 200.

In FIG. 3, each of the memory cell strings (e.g., memory cell strings 231a, 232a, 233a, 234a, 231b, and 234b) of memory device 200 can include one of memory cells 210, one of memory cells 211, one of memory cells 212, and one of memory cells 213. FIG. 3 shows an example of four memory cells 210, 211, 212, and 213 in each memory cell string. The number of memory cells in each memory cell string can vary.

As shown in FIG. 3, each of select circuits (e.g., drain select circuits) 241a, 242a, 243a, 244a, 241b, and 244b can include a select gate 260. FIG. 3 shows an example where memory device 200 includes one drain select gate (e.g., select gate 260) in each drain select circuit. However, memory device 200 can include multiple drain select gates in each drain select circuit, depending on the number of drain select lines associated with each drain select circuit. The number of drain select gates in each drain select circuit can be equal to the number of drain select lines associated with each drain select circuit.

Each of select circuits (e.g., source select circuits) 241′a, 242′a, 243′a, 244′a, 241′b, and 244′b can include a select gate 264. FIG. 3 shows an example where memory device 200 includes one source select gate (e.g., select gate 264) in each source select circuit. However, memory device 200 can include multiple source select gates in each source select circuit, depending on the number of source select lines associated with each source select circuit. The number of source select gates (e.g., one in the example of in FIG. 3) in each source select circuit can be equal to the number of source select lines (e.g., one in the example of in FIG. 3) associated with each source select circuit.

Each of select gates 260 and 264 can operate as a transistor. For example, select gate 260 of select circuit 241a can operate as a field effect transistor (FET), such as a metal-oxide semiconductor FET (MOSFET). An example of such a MOSFET includes an n-channel MOS (NMOS) transistor.

As shown in FIG. 3, a select line shared among particular select circuits can be shared by respective select gates of those particular select circuits. For example, select line 280₀ of sub-block SB0 of block BLK0 can be shared by select gates 260 of select circuits 241a, 242a, and 243a of sub-block SB0 of block BLK0. In another example, select line 284 of sub-block SB0 of block BLK0 can be shared by select gates 264 of select circuits 241′a, 242′a, and 243′a of sub-block SB0 of block BLK0.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a of sub-block SB0 of block BLK0) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor (e.g., FET)) between the portion of the conductive material and the portion of the channel material.

FIG. 4A shows a side view (e.g., cross-section) of a structure of a portion of memory device 200 of FIG. 3 including control gates 220₀, 221₀, 222₀, and 223₀ of block BLK0, control gates 220₁, 221₁, 222₁, and 223₁ of block BLK1, pillars 450 (memory cell pillars) in respective blocks BLK0 and BLK1, and a dielectric structure 451 between blocks BLK0 and BLK1, according to some embodiments described herein. FIG. 4B shows a top view (e.g., cross-section) of a portion of a control gate 223₀ and an adjacent pillar 450 of memory device 200 taken along line 4B-4B of FIG. 4A. FIG. 4C shows a portion of a top view of memory device 200 of FIG. 4A including relative locations of blocks BLK0 and BLK1, dielectric structure 451, pillars 450, and data lines 270₀, 270₁, 270₂, and 270₃. The following description refers to FIG. 4A.

The structure of memory device 200 in FIG. 4A corresponds to part of the schematic diagram of memory device 200 shown in FIG. 3. For simplicity, some elements of memory device 200 of FIG. 3 are omitted from the structure of the portion of memory device 200 shown in FIG. 4A.

For simplicity, cross-section lines (e.g., hatch lines) are omitted from some or all the elements shown in the drawings described herein. Some elements of memory device 200 (and other memory devices described herein) may be omitted from a particular figure of the drawings so as not to obscure the view or the description of the element (or elements) being described in that particular figure. Further, the dimensions (e.g., physical structures) of the elements shown in the drawings described herein are not scaled.

As shown in FIG. 4A, memory device 200 can include a substrate 499 over which memory cells 210, 211, 212, and 213 of memory cell strings 231a, 234a, 231b, and 234b of respective sub-blocks SB0 and SB1 of blocks BLK0 and BLK1 can be formed (e.g., formed vertically in the z-direction with respect to source 290 and substrate 499). Dielectric structure 451 can separate (electrically separate) block BLK0 from block BLK1, such that control gates 220₀, 221₀, 222₀, and 223₀ are separated (electrically separated) from control gates 220₁, 221₁, 222₁, and 223₁ by dielectric structure 451. Dielectric structure 451 can have a depth (e.g., height) in the Z-direction. FIG. 4A shows an example where dielectric structure 451 can extend to a data line (e.g., data line 270₀), such that the depth of dielectric structure 451 can be a distance (e.g., vertical distance) between source 290 and the data line. However, dielectric structure 451 can extend from source 290 to level 451Z (e.g., not touching line data line 270₀), such that the depth of dielectric structure 451 can be a distance (e.g., vertical distance) between source 290 and to level 451Z.

As shown in FIG. 4A, memory device 200 can include levels 409 through 414, and levels 409′ through 413′ interleaved with levels 409 through 414 in the Z-direction. Levels 409 through 414 and levels 409′ through 413′ are internal physical levels (e.g., layers of materials) of memory device 200 between substrate 499 and data line 270₀.

Substrate 499 of memory device 200 can include monocrystalline (also referred to as single-crystal) semiconductor material. For example, substrate 499 can include monocrystalline silicon (also referred to as single-crystal silicon). The monocrystalline semiconductor material of substrate 499 can include impurities, such that substrate 499 can have a specific conductivity type (e.g., n-type or p-type).

As shown in FIG. 4A, memory device 200 can include circuitry 495 located in (e.g., formed in) substrate 499. At least a portion of circuitry 495 (e.g., the entire circuitry 495 or only a portion of circuitry 495) can be located in a portion of substrate 499 that is under (e.g., directly under) memory cell strings 231a, 234a, 231b, and 234b. Circuitry 495 can include circuit elements (e.g., transistors T1 and T2 and other transistors (not shown)) coupled to other circuit elements outside substrate 499. For example, data lines 270₀ (FIG. 4A) and control gates 220₀, 221₀, 222₀, 223₀ of block BLK0 and control gates 220₁, 221₁, 222₁, and 223₁ of block BLK1 can be coupled to circuit elements in circuitry 495 of memory device 200. Circuitry 495 can include decoder circuits, driver circuits, buffers, sense amplifiers, charge pumps, and other circuitry of memory device 200. Transistors T1 and T2 (and other transistors, not shown) of circuitry 495 can be part of (e.g., can represent) such decoder circuits, driver circuits, buffers, sense amplifiers, charge pumps, and other circuitry of memory device 200.

Source 290 can include a conductive material (or materials (e.g., different levels of materials)) and can have a length extending in the X-direction. FIG. 4A shows an example where source 290 can be formed over a portion of substrate 499 (e.g., by depositing a conductive material over substrate 499). Alternatively, source 290 can be formed in or formed on a portion of substrate 499 (e.g., by doping a portion of substrate 499).

As shown in FIG. 4A, select lines (e.g., drain select lines) 280₀ and 280₁ of each of blocks BLK0 and BLK1 can be located in level 414. Select line 284 (e.g., source select line) of each of blocks BLK0 and BLK1 can be located in the same level (e.g., level 409) between substrate 499 and memory cell strings 231a, 234a, 231b, and 234b. The memory cells of a respective memory cell string (memory cell strings 231a, 234a, 231b, and 234b) can be located on different levels among levels 410 through 413.

As shown in FIG. 4A, memory device 200 can include conductive structures 275 coupled between respective pillars 450 and data line 270₀. Conductive structures 275 can be part of circuit paths (e.g., current paths) between data line 270₀ and respective pillars 450.

As shown in FIG. 4A, a select line (e.g., 280₀) can be a structure (e.g., a level) of a conductive material (e.g., a layer (e.g., a piece) of conductive material 422) located in a single level of memory device 200. As described above, a select line can carry a signal (e.g., signal SGD0₀) but it does not operate like a switch (e.g., a transistor). A select gate (e.g., 260) can include a portion of a respective select line (e.g., a portion of the piece of conductive material 422 that forms the respective select line) and additional structures to perform a function (e.g., function of a transistor). For example, in FIG. 4A, select gate 260 of sub-block SB0 of block BLK0 can include a portion of select line 280₀ of sub-block SB0 of block BLK0 and a portion of pillar 450 adjacent select line 280₀ of sub-block SB0 of block BLK0.

As shown in FIG. 4A, memory cells 210, 211, 212, and 213 (associated with respective pillars 450) of memory cell strings 231a, 234a, 231b, and 234b can be located in levels 410, 411, 412, and 413, respectively. Control gates 220₀, 221₀, 222₀, and 223₀ (associated with memory cells 210, 211, 212, and 213, respectively) of block BLK0 can be located in levels 410, 411, 412, and 413, respectively, adjacent respective portions 450W (e.g., sidewalls) of pillars 450 in block BLK0. Control gates 220₁, 221₁, 222₁, and 223₁ (associated with memory cells 210, 211, 212, and 213, respectively) of block BLK1 can be located in levels 410, 411, 412, and 413, respectively, adjacent respective portions (e.g., sidewalls) 450W of pillars 450 in block BLK1. As shown in FIG. 4A, control gates 220₀, 221₀, 222₀, and 223₀ can be located on the same levels at which control gates 220₁, 221₁, 222₁, and 223₁, respectively, are located.

Memory device 200 can include dielectric materials 421 (e.g., levels of dielectric materials) on respective levels 409′ through 413′ interleaved (in the Z-direction) with conductive materials 422 (e.g., levels of conductive materials) on respective levels 409 through 414. Dielectric materials 421 can include silicon dioxide or other dielectric material. Example of conductive materials 422 include tungsten, molybdenum, or other conductive materials.

Conductive materials 422 on levels 409, 410, 411, and 412 can form (e.g., can be materials included in) respective control gates 220₀, 221₀, 222₀, and 223₀ of block BLK0, and control gates 220₁, 221₁, 222₁, and 223₁ of block BLK1. Conductive materials 422 on levels 409 and 414 can form (e.g., can be materials included in) respective select gate (e.g., drain select gate associated with signals SGD₀ through SGD₁, and source select gate associated with signal SGS0) of memory device 200. For simplicity, FIG. 4A omits dielectric materials (e.g., silicon dioxide) located between other elements of memory device 200.

Memory device 200 also includes a dielectric liner 452 (not shown in FIG. 4A) adjacent respective conductive materials 422 on levels 409 through 414. For simplicity, dielectric liner 452 is not shown in FIG. 4A. However, other figures (e.g., FIG. 4B, FIG. 4D, and FIG. 4E) show dielectric liner 452.

As shown in FIG. 4A, memory device 200 can include pillars 450 (memory cell pillars) in respective blocks BLK0 and BLK1. Each of pillars 450 can be part of a respective memory cell string. Each of pillars 450 can have length extending (e.g., extending vertically in the direction of the Z-direction). As shown in FIG. 4A, the Z-direction is also a direction parallel to a direction from one control gate (e.g., control gates 220₀) to another control gate (e.g., control gates 220₁) of the same block (e.g., block BLK0). The Z-direction is also a direction perpendicular to a direction from one block (e.g., BLK0) to another block (e.g., block BLK1) of memory device 200.

As shown in FIG. 4A, memory cells 210, 211, 212, and 213 and control gates 220₀, 221₀, 222₀, 223₀, 220₁, 221₁, 222₁, and 223₁ can be located (e.g., stacked in one level (e.g., layer) over another in the Z-direction) along respective portions (e.g., segments) of pillars 450 in the Z-direction.

Memory device 200 can include a structure 430 and a dielectric material 405 that can be part of a respective pillar of pillar 450. Structure 430 and dielectric material 405 can extend continuously along a length (in the Z-direction) of the respective pillar 450. Dielectric material 405 can include silicon dioxide or other dielectric materials. Structure 430 can be coupled to (electrically coupled to) source 290 and a respective data line (e.g., data line 270₀). Structure 430 of a respective pillar 450 is adjacent (e.g., contacts) portions of respective control gates. For example, structure 430 of pillar 450 in block BLK0 is adjacent (e.g., contacts) control gates 220₀, 221₀, 222₀, and 223₀ of block BLK0. In another example, structure 430 of pillar 450 in block BLK1 is adjacent (e.g., contacts) control gates 220₁, 221₁, 222₁, and 223₁ of block BLK1.

As shown in FIG. 4A, structure 430 can include portions 401, 402, 403, and 404. Each of memory cells 210, 211, 212, and 213 of a memory cell string can include part of each of portions 401, 402, 403, and 404 that is located adjacent one of the control gates (one of control gates 220₀, 221₀, 222₀, and 223₀, 220₁, 221₁, 222₁, and 223₁). For example, memory cell 213 of memory cell string 231a can include part of structure 430 (portions 401, 402, 403, and 404) on level 413 that is adjacent control gates 223₀. In another example, memory cell 212 of memory cell string 231a can include part of structure 430 (portions 401, 402, 403, and 404) on level 412 that is adjacent control gates 222₀.

Structure 430 can include a conductive structure (e.g., portion 404) that can be part of a conductive path (e.g., pillar channel structure) to conduct current between data line 270₀ and source 290. Structure 430 can be part of an ONOS (SiO₂, Si₃N₄, SiO₂, Si) structure. For example, portion 401 can include SiO₂, and can be combined with part of an adjacent control gate to form a charge blocking material (or materials) that is capable of blocking a tunneling of a charge. Portion 402 can include a charge storage element (e.g., charge storage portion, charge storage material (or materials), such as Si₃N₄) that can provide a charge storage function (e.g., trap charge) to represent a value of information stored in memory cells 210, 211, 212, or 213. Portion 403 can include a dielectric, such as a tunnel dielectric material or materials (e.g., SiO₂), that is capable of allowing tunneling of a charge (e.g., electrons). Portion 404 can include polysilicon (e.g., doped or undoped polysilicon) and can be a channel structure (e.g., pillar channel) that can conduct current during operation of memory device 200. As an example, portion 403 can allow tunneling of electrons from portion 404 to portion 402 during a write operation and tunneling of electrons from portion 402 to portion 404 during an erase operation of memory device 200. Moreover, portion 403 can allow tunneling of holes from portion 404 to portion 402, compensating the trapped electron recombination during an erase operation of memory device 200.

The arrangement of structure 430 shown in FIG. 4A is an example. In an alternative arrangement, structure 430 can be part of a SONOS (Si, SiO2, Si3N4, SiO2, Si) structure, a TANOS (TaN, Al₂O₃, Si₃N₄, SiO₂, Si) structure, a MANOS (metal, Al₂O₃, Si₃N₄, SiO₂, Si) structure, or other structures. In another alternative arrangement, structure 430 can be part of a floating gate structure (e.g., portion 402 can be polysilicon). FIG. 4A shows an example of structure 430 having a particular shape (e.g., the shape shown in FIG. 4A). However, structure 430 can have a different shape.

FIG. 4B shows a cross-section of a portion of memory device 200 (taken along line 4B-4B of FIG. 4A) including a portion of control gate 223₀ (formed by conductive materials 422) and adjacent pillar 450 at memory cell 213 of memory cell string 231a, according to some embodiments described herein. Other control gates and pillars of memory cell strings of memory device 200 have similar or the same structure shown in FIG. 4B.

As shown in FIG. 4B, control gate 223₀ can include (e.g., can be formed from) a combination of materials, conductive material 422 adjacent (and surrounding) a dielectric liner 452. Dielectric liner 452 is adjacent (e.g., contacts) portion 450W of pillar 450.

Dielectric liner 452 can be structured (e.g., configured) to shield (e.g., protect) the dielectric material (e.g., silicon dioxide) of portion 401 of pillar 450 from some processes (e.g., etch processes) during the processes of forming memory device 200, for example, processes of forming part of control gate 223₀ and part of other control gates of memory device 200. Dielectric liner 452 can also be structured (e.g., configured) to block a tunneling of charge from pillar 450 (e.g., from portion 402 (e.g., charge storage portion) of pillar 450) to other portions (e.g., conductive material 422) of control gate 223₀.

Dielectric liner 452 can include a high-k (or hi-k) dielectric material or a combination of high-k dielectric materials. A high-k dielectric material is a dielectric material that has a dielectric constant greater than the dielectric constant of silicon dioxide. For example, dielectric liner 452 can include aluminum oxide (AlOx). In another example, dielectric liner 452 can include titanium silicon nitride (TiSiN). In another example, dielectric liner 452 can contain hafnium. Examples of dielectric liner 452 containing hafnium include hafnium oxide (HfOx) and hafnium silicate (HfSiOx).

The materials of dielectric liner 452 listed herein are examples. However, other dielectric materials (e.g., other high-k dielectric materials) can be used. For example, other dielectric materials having a dielectric constant greater than the dielectric constant of aluminum oxide can be used.

FIG. 4C shows a top view of memory device 200 of FIG. 4A including relative locations of the blocks (e.g., blocks BLK0 and BLK1), dielectric structure 451, pillars 450 of memory cell strings, and data lines 270₀, 270₁, 270₂, and 270₃. For simplicity, not all memory cell strings (which include respective pillars 450) in FIG. 4C are labeled. Some of the elements of memory device 200 of FIG. 4C are not shown in FIG. 2 through FIG. 4A including data line 270₃ (and associated signal BL₃) and memory cell strings coupled to data line 270₃.

As shown in FIG. 4C, data lines 270₀, 270₁, 270₂, and 270₃ can be located over (with respect to the Z-direction) and extend across (in the X-direction) the blocks (e.g., blocks BLK0 and BLK1) of memory device 200. Each of data lines 270₀, 270₁, 270₂, and 270₃ can be electrically coupled to respective pillars 450 of blocks BLK0 and BLK1. A portion of memory device 200 along line 4A-4A is shown in FIG. 4A.

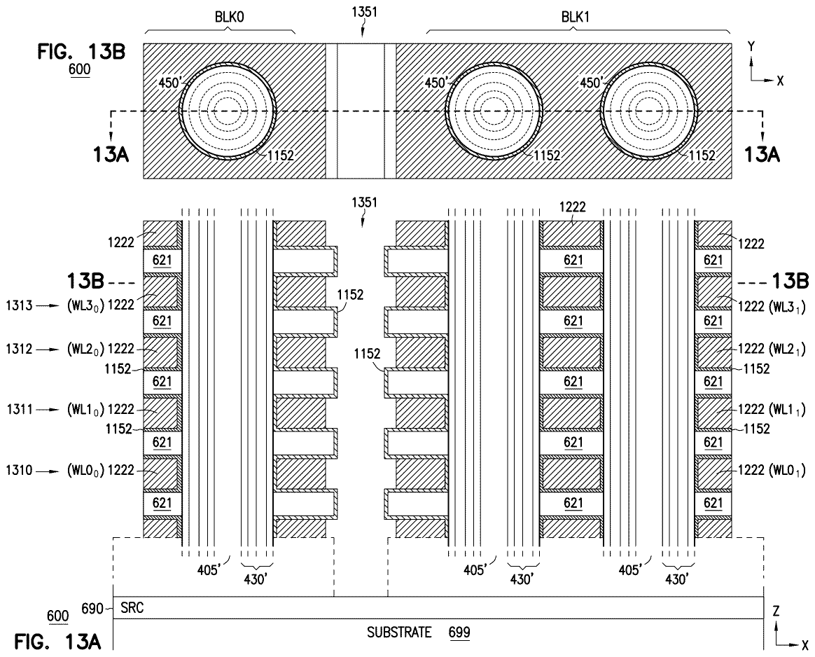

As shown in FIG. 4C, dielectric structure 451 can be located (e.g., can be formed) in a slit (e.g., a trench) 451′ between blocks BLK0 and BLK1. In an example, slit 451′ can be similar to (or the same as slit 1351 of FIG. 13A). As shown in FIG. 4C, dielectric structure 451 can include dielectric materials 451D1 and 451D2, and 451D3. Dielectric structure 451 can also include a material 451P (under and hidden from the view of dielectric material 451D3, but shown in FIG. 4E). FIG. 4D shows a side view (e.g., cross-section) taken along line 4D-4D of FIG. 4C including a portion of dielectric structure 451 of FIG. 4C. FIG. 4E shows a side view (e.g., cross-section) of a portion of memory device 200 taken along line 4E-4E of FIG. 4C including a portion of dielectric structure 451 and adjacent pillars 450 (memory cell pillars).

As shown in FIG. 4D, each of dielectric material 451D3 and material 451P can between (in the X-direction) respective portions of dielectric materials 451D1 and 451D2. Dielectric Material 451D3 can be located (e.g., formed) over material 451P, such that material 451P can be between (in the Z-direction) dielectric material 451D3 and source 290. Dielectric material 451D3 and material 451P can be different from each other. Material 451P can be different from dielectric materials 451D1 and 451D2. For example, material 451P can include a non-oxide material. In an example, material 451P can include a semiconductor material. As an example, material 451P can include polysilicon. As an example, dielectric material 451D3 can include silicon dioxide.

In FIG. 4E, for simplicity, a portion (e.g., bottom portion) of memory device 200 (e.g., the portion below the control gate associated with signal WL1₀) is omitted. As shown in FIG. 4E, each control gate (e.g., control gate associated with signal WL2₀) can include a combination of a level of conductive material 422 and dielectric liner 452, in which the combination is between two adjacent levels of dielectric materials 421.

As shown in FIG. 4E, each dielectric liner 452 can include dielectric portions 452A, 452B, and 452C adjacent a respective level of conductive material 422. For simplicity, only some of dielectric liners 452 (and corresponding dielectric portions 452A, 452B, and 452C) are labeled in FIG. 4E.

As shown in FIG. 4E, dielectric portion 452A is between (and adjacent) a respective level of conductive material 422 and a respective level of dielectric materials 421. Dielectric portion 452B is between (and adjacent) a respective level of conductive material 422 and a respective level of dielectric materials 421. Dielectric portion 452C can extend in the Z-direction direction and is coupled to (joining) dielectric portions 451A and 451C.

As shown in FIG. 4E, dielectric portion 452A can include a thickness (not labeled) in the Z-direction and an edge (e.g., a vertical sidewall portion) 452E′ in the Z-direction. Dielectric portion 452B can include a thickness (not labeled) in the Z-direction and an edge (e.g., a vertical sidewall portion) 452E″ in the Z-direction.

Each level of conductive material 422 can include a thickness (not labeled) in the Z-direction and an edge (e.g., a vertical sidewall portion) 422E in the Z-direction. The thickness of a level of conductive material 422 can be greater than the thickness of each of dielectric portions 452A and 452B. Each level of dielectric materials 421 can include a thickness (not labeled) in the Z-direction and an edge (e.g., a vertical sidewall portion) 421E in the Z-direction.

As shown in FIG. 4E, the Z-direction can also be a direction from one level of conductive material 422 to another level of conductive material 422. The Z-direction can also be a direction from one level of conductive material 422 to another level of conductive material 422. The Z-direction can also be a direction from one dielectric material 421 to another level of dielectric materials 421. The Z-direction can also be a direction from one from a level of conductive material 422 to a level of dielectric material 421.

FIG. 4E shows distances X1, X2, X3, and X4. Each of distances X1, X2, X3, and X4 can be measured (e.g., in a fraction of meter unit) from the same reference location relative to the X-direction. FIG. 4E shows an example reference location being portion 450W (e.g., part of a sidewall) of pillar 450. Thus, in this example, distance X1 can be measured from portion 450W of pillar 450 to edge 452E′ of dielectric portion 451A. Distance X2 can be measured from portion 450W of pillar 450 to edge 452E″ of dielectric portion 451B. Distance X3 can be measured from portion 450W of pillar 450 to edge 422 of level of conductive material 422. Distance X4 can be measured from portion 450W of pillar 450 to edge 421 of level of dielectric material 421.

As shown in FIG. 4E, distance X4 is greater than each of distances X1, X2, and X3. Distance X1 can be the same as distance X2 (e.g., X1=X2). Distance X3 is not greater than (e.g., less than) each of distances X1 and X2 (e.g., X3<X1 and X3<X2).

Thus, as shown in FIG. 4E, edge 422E of a respective level of conductive material 422 is closer to pillar 450 (in the X-direction) than edge 452E′ of dielectric portion 452A adjacent the respective level of conductive material 422. This also means that from the same reference location (e.g., portion 450W), dielectric portion 452A can have a dimension (e.g., corresponding to distance X1) in the x-direction that is greater (e.g., longer) than a dimension (e.g., corresponding to distance X3) of level of conductive material 422.

As shown in FIG. 4E, edge 422E of a respective level of conductive material 422 is closer to pillar 450 (in the X-direction) than edge 452E″ of dielectric portion 452 adjacent the respective level of conductive material 422. This also means that from the same reference location (e.g., portion 450W), dielectric portion 452B can have a dimension (e.g., corresponding to distance X2) in the x-direction that is greater (e.g., longer) than a dimension (e.g., corresponding to distance X3) of level of conductive material 422.

Similarly, in block BLK1, dielectric portions 452A and 452B, level of conductive material 422, and level of dielectric material 421 can include respective edges 452E′, 452E″, 422E, and 421E with corresponding distances X1′, X2′, X3′, and X4′ relative to portion 450W of pillar 450 of block BLK1. Distances X1′, X2′, X3′, and X4′ can have relationships similar to that of distances X1, X2, X3, and X4. For example, distance X4′ is greater than each of distances X1′, X2′, and X3′. Distance X1′ can be the same as distance X2′ (e.g., X1′=X2′). Distance X3′ is not greater than (e.g., less than) each of distances X1′ and X2′ (e.g., X3′<X1′ and X3′<X2′).

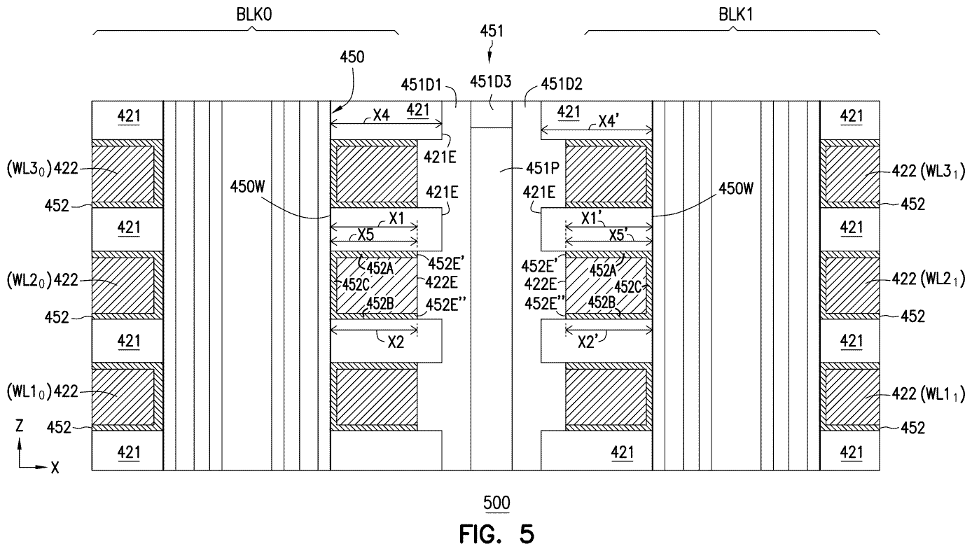

FIG. 5 shows a memory device 500 that can be a variation of memory device 200 of FIG. 4E including variation of dielectric liner 452, according to some embodiments described herein. Memory device 500 includes elements that are similar to or the same as those of memory device 200. Thus, for simplicity, descriptions of similar to the same elements between memory devices 200 and 500 are not repeated.

As shown in FIG. 4E and FIG. 5, differences between memory devices 200 and 500 include the dimensions of dielectric liner 452 of memory device 500. As shown in FIG. 5, each conductive material 422 adjacent dielectric structure 451 can have a dimension corresponding to distance X5. Distance X5 can be measured from portion 450W of pillar 450 to edge 422E of a respective level of conductive material 422. As shown in FIG. 5, distance X5 can be the same as (e.g., equal to) each of distance X1 and distance X2 (e.g., X5=X1 and X5=X2). Thus, as shown in FIG. 4E, each of edges 452E′ and 452E″ is not closer to pillar 450 (in the X-direction) than edge 422E. The distance (X5) between edge 422E and pillar 450 can be the same as the distance (X1 or X3) between edge 452E′ (or edge 452E″) and pillar 450. This means that from the same reference location (e.g., portion 450W), each of dielectric portions 452A and 452B can have a dimension (e.g., corresponding to distance X1 or X2) in the x-direction that is the same as (e.g., not longer than) a dimension (e.g., corresponding to distance X3) of a level of conductive material 422.

Similarly, in block BLK1, each level of conductive material 422 adjacent dielectric structure 451 can include a respective 422E′ with corresponding distance X5′ relative to portion 450W of pillar 450 of block BLK1. Distance X1′, X2′, and X5′ can have relationships similar to that of distances X1, X2, and X5. For example, distance X5′ can be the same as (e.g., equal to) each of distance X1′ and distance X2′ (e.g., X5′=X1′ and X5′=X2′).

Memory devices 200 or 500 can include the following improvement and benefit in comparison with some alternation memory device structures. For example, in an alternative structure (not shown) of memory device 200, dielectric liner 452 can be formed such that distance X3 (FIG. 4E) is greater than each of distance X1 and X2 (e.g., X3>X1 and X3>X2). This means that in such an alternative structure, edge 422E is farther from pillar 450 (in the X-direction) than each of edge 452E′ and 452E″. This also means that from the same reference location (e.g., portion 450W), each of dielectric portions 452A and 452B can have a dimension in the x-direction that is less than (e.g., shorter than) a dimension of level of conductive material 422 adjacent dielectric structure 451.

The shorter dimensions of dielectric portions 452A and 452B in the alternative structure described above can result in conductive material 422 and dielectric materials 421 having more contact area with adjacent dielectric materials 421 at the location of dielectric structure 451 in comparison with the contact area between conductive material 422 and adjacent dielectric materials 421 of FIG. 4E or FIG. 5. This can cause the alternative structure to be susceptible to structural damage at the location between conductive material 422 and adjacent dielectric materials 421 at dielectric structure 451. For example, in the alternative structure, such a structural damage could be caused by breakdown in dielectric material between adjacent control gates, or conductive material migration (e.g., short) between adjacent control gates, or both. The risk for such a structural damage can be higher for conductive materials 422 having a relatively lower melting point (e.g., molybdenum) than it would be for conductive materials 422 having a relatively higher melting point (e.g., tungsten or a combination of tungsten and titanium nitride). The risk for such a structural damage can also increase when the thickness (a tier thickness in the Z-direction) of conductive materials 422 is reduced to a certain thickness. The structural damage described herein can lead to reduced yield and degradation in device performance.

In the memory devices described herein (e.g., memory devices 200, and 500), including the described dielectric liners (e.g., dielectric liners 452 as described above and dielectric liners 1152, described below) having structures with a certain dimension (e.g., dimension corresponding to distance X1 or X2) relative to the dimension (e.g., dimension corresponding to distance X3) of conductive material 422 can mitigate the structural damage mentioned above. This leads to improve yield and performance associated with the memory devices described herein.

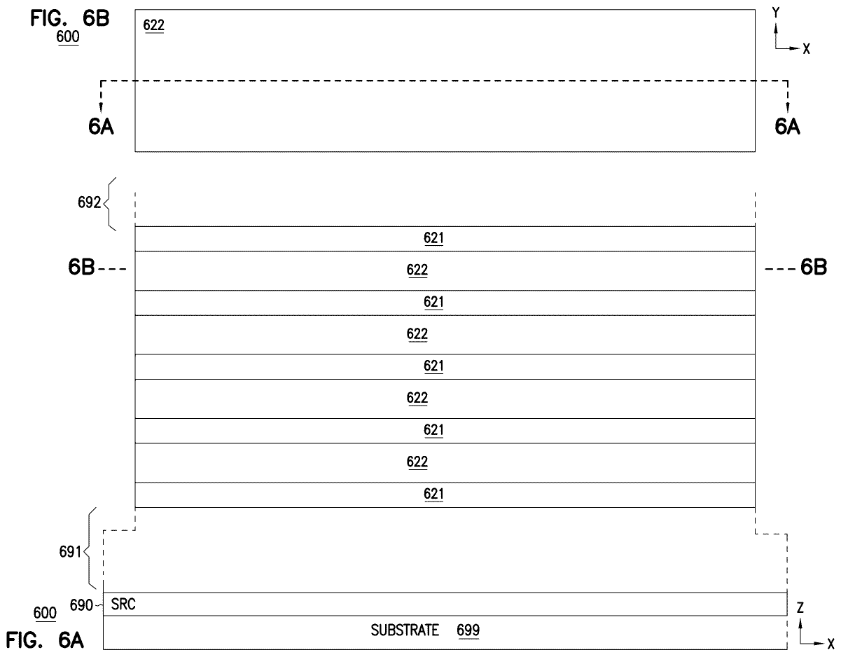

Some or all of the structure of memory devices 200 and 500 shown in FIG. 2 through FIG. 5 can be formed using processes associated with the processes described below with reference to FIG. 6A and FIG. 6B through FIG. 20.

FIG. 6A and FIG. 6B through FIG. 20 show different views of elements during processes of forming a memory device 600, according to some embodiments described herein. FIG. 6A shows a side view (e.g., cross-section) in the X-direction of memory device 600 after dielectric materials (levels of dielectric materials) 621 and dielectric materials (levels of dielectric materials) 622 are alternatively formed over a substrate 699. Substrate 699 is similar to (e.g., can correspond to) substrate 499 (FIG. 4A) of memory device 200. Dielectric materials 621 and 622 can be sequentially formed one material after another over substrate 699 in an interleaved fashion, such that dielectric materials 621 can be interleaved with dielectric materials 622.

FIG. 6B shows a top view of a portion (e.g., in the X-Y plane) of memory device 600 taken along line 6B-6B of FIG. 6A. The side view (in the X-Z direction) of memory device 600 shown in FIG. 6A is taken along line (e.g., cross-section line) 6A-6A of FIG. 6B.

As shown in FIG. 6A, the process of forming memory device 600 can include forming a material 690 over substrate 699. Material 690 can form part of a source (e.g., associated with signal SRC) that is similar to source 290 of FIG. 4A.

One skilled in the art would readily recognize that the process of forming memory device 600 described herein with reference to FIG. 6A and FIG. 6B through FIG. 18A and FIG. 18B can include forming additional elements (not shown) in portions 691 and 692 (shown in dashed lines) of memory device 200 in FIG. 6A. For example, the additional elements in portion 691 can include select circuits similar to select circuits 241′a, 244′a, 241′b, and 244′b (e.g., source select circuit) and other elements of memory device 200 (FIG. 2, FIG. 3, and FIG. 4A). In another example, the additional elements in portion 692 can include select circuits similar to select circuits 241a, 244a, 241b, and 244b (e.g., drain select circuit) and other elements of memory device 200 (FIG. 2, FIG. 3, and FIG. 4A). For simplicity and not to obscure the embodiments described herein, description of formation of such additional elements in portions 691 and 692 is omitted from the description herein.

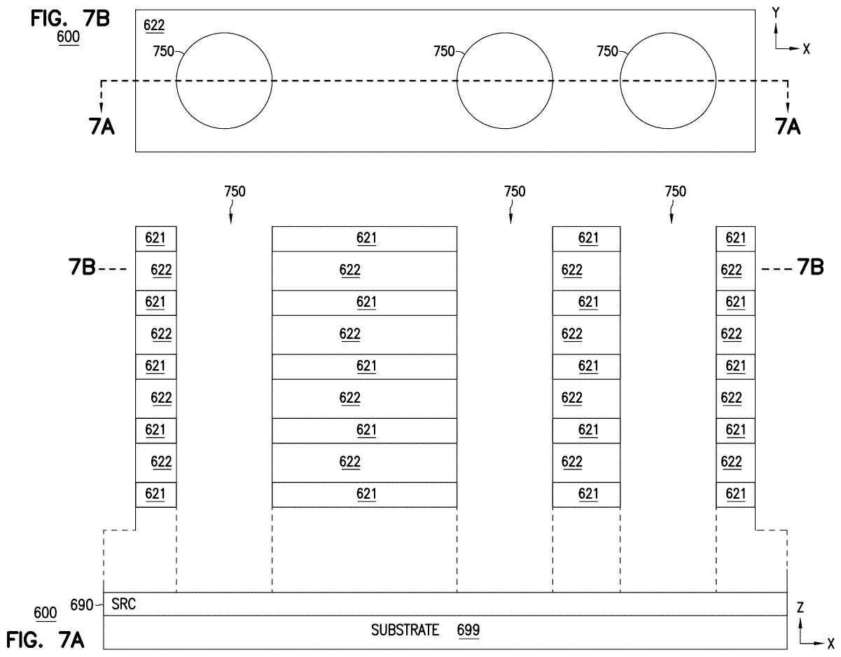

In the following description, different views of memory device 600 in subsequent processes are based on the views of memory device 600 of FIG. 6A and FIG. 6B and follow the same arrangement of the views (e.g., side view and top view) of FIG. 6A and FIG. 6B. For example, FIG. 7A shows a side view of a portion of memory device 600 taken along line (e.g., cross-section line) 7A-7A of FIG. 7B. FIG. 7B shows a top view of a portion of memory device 600 of FIG. 7A taken along line 7B-7B of FIG. 7A. For simplicity, the following description omits repeating specific views (e.g., side view and top view) and specific cross-section lines of portion of memory device 600 from one process to the next.

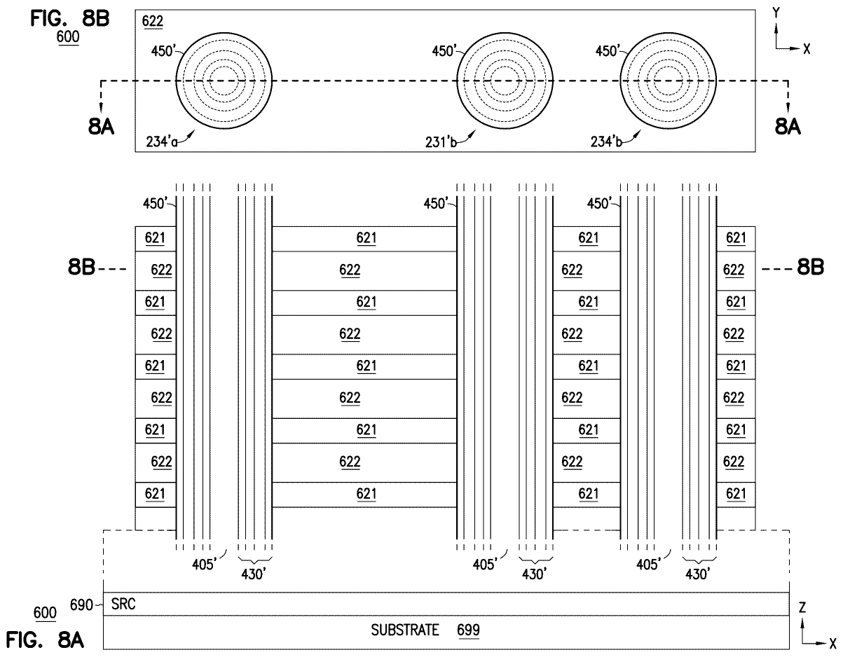

In the description herein, elements given the same numerical labels are similar or the same elements. For example, pillar 450 (FIG. 4A) and pillar 450′ (FIG. 8A) are similar or the same elements. Thus, for simplicity, the detailed description of similar or the same elements may not be repeated.

FIG. 7A and FIG. 7B show different views of memory device 600 after openings (e.g., holes) 750 are formed through dielectric materials 621 and 622. Forming openings 750 can include removing (e.g., etching) a portion of dielectric materials 621 and 622 at the locations of openings 750.

FIG. 8A and FIG. 8B show different views of memory device 600 after pillars 450′ are formed. Forming pillars 450′ can include forming a structure 430′ and a dielectric material 405′ in respective openings 750. Pillars 450′ are similar to (e.g., can correspond to) pillars 450 of FIG. 4A. Structure 430′ and dielectric material 405′ are similar to (e.g., can correspond to) structure 430 and dielectric material 405, respectively, of FIG. 4A. Like structure 430 of FIG. 4A, structure 430′ in FIG. 8A can form part of memory cells (e.g., like memory cells 210, 211 212, and 213 of FIG. 4A) of a respective memory cell string of memory device 600 of FIG. 8A. Pillars 450'of respective memory cell strings 234′a, 231′b, and 234′b of memory device 600 shown in FIG. 8A and FIG. 8B are similar to (e.g., can correspond to) pillars 450 of memory cell strings 231a, 234b, and 234b, respectively, of memory device 200 of FIG. 4A and FIG. 4C.

In FIG. 8A, a level (e.g., a layer) of dielectric material 622 (or alternatively, two adjacent levels that include a level of dielectric material 621 and a level of dielectric material 622) can be called a tier of memory device 200. As shown in FIG. 8A, the tiers of memory device 600 can be located (e.g., stacked) one over another in the Z-direction over substrate 699, such that two adjacent tiers can be separated from each other by a respective level (e.g., layer) of dielectric material (e.g., silicon dioxide) 621. FIG. 8A shows an example of a specific number of tiers (e.g., four tiers). However, memory device 200 can include up to (or more than) a hundred tiers.

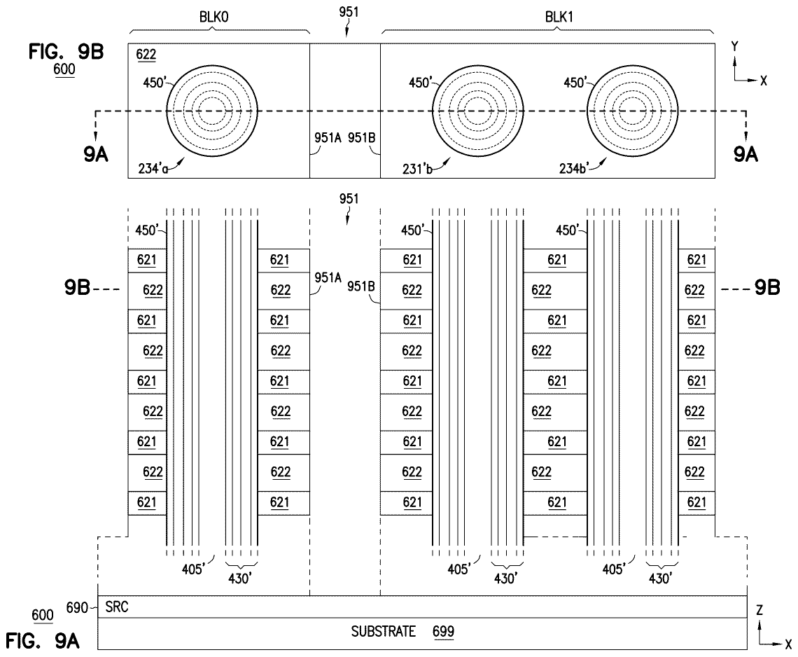

FIG. 9A and FIG. 9B show memory device 600 after a slit 951 (e.g., an opening, a trench, or a cut) is formed. Slit 951 can be formed such that it can extend through the levels of dielectric materials 621 and 622. Slit 951 can include sidewalls 951A and 951B opposite from each other in the X-direction. As shown in FIG. 9A, sidewalls 951A and 951B can include respective portions of dielectric materials 621 and 622 exposed at slit 951. Each of sidewalls 951A and 951B can include a height in the Z-direction, a width in the X-direction, and a length (which is greater than the width) in the Y-direction.

Slit 951 can be formed to divide (e.g., separate) elements (e.g., respective memory cell strings and other elements) of memory device 600 into portions that can become part of respective blocks (e.g., blocks BLK0 and BLK1) of memory device 600. For example, slit 951 can separate dielectric materials 621 and 622 into respective portions in blocks BLK0 and BLK1. In another example, slit 951 can separate pillars 450′ of respective memory cell strings of memory device 600 into respective portions in blocks BLK0 and BLK1. As shown in FIG. 9A and FIG. 9B, pillar 450′ of memory cell string 234′a can be part of block BLK0. Pillars 450′ of memory cell strings 231′b and 234′b can be part of block BLK1.

The following descriptions involve processes that include removing and then replacing the levels of dielectric materials (e.g., silicon nitride) 622 with respective levels of materials to form respective control gates in respective tiers in memory device 600.

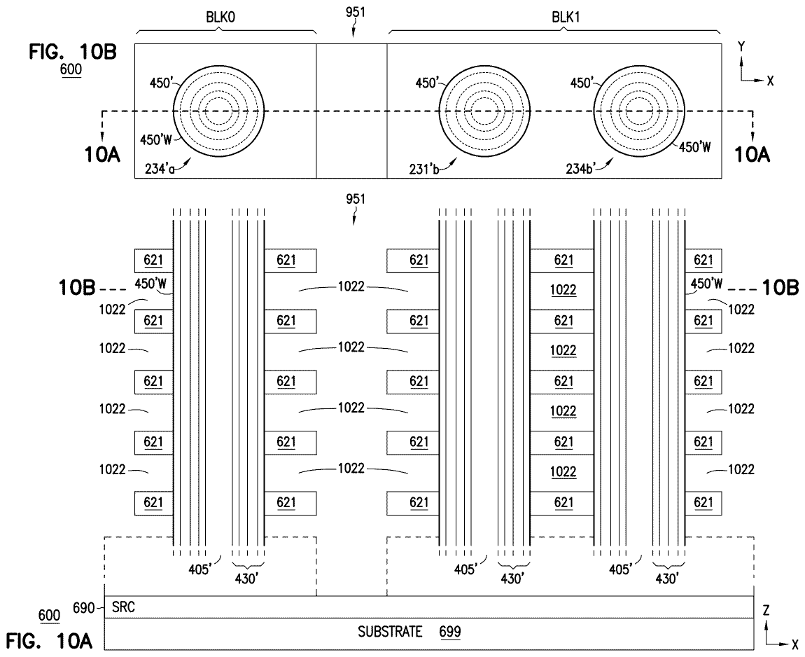

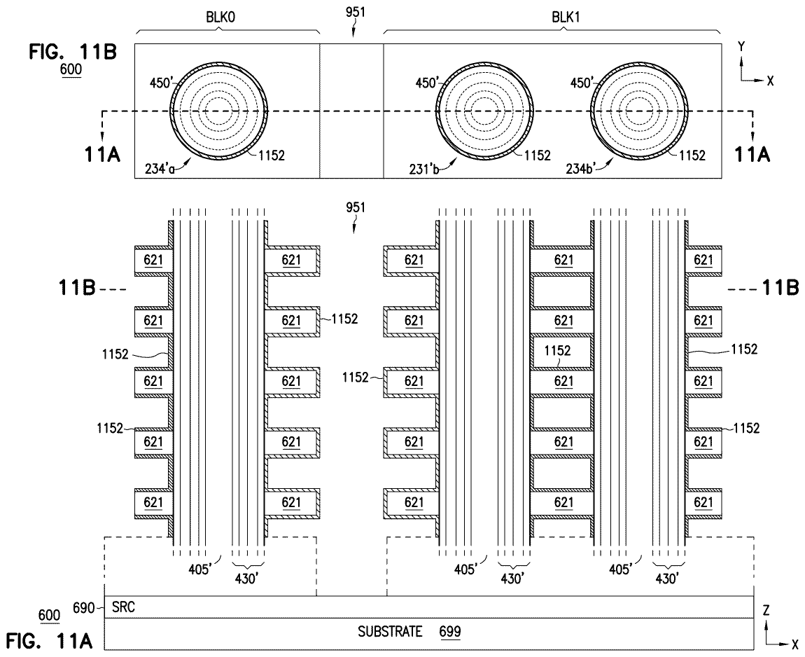

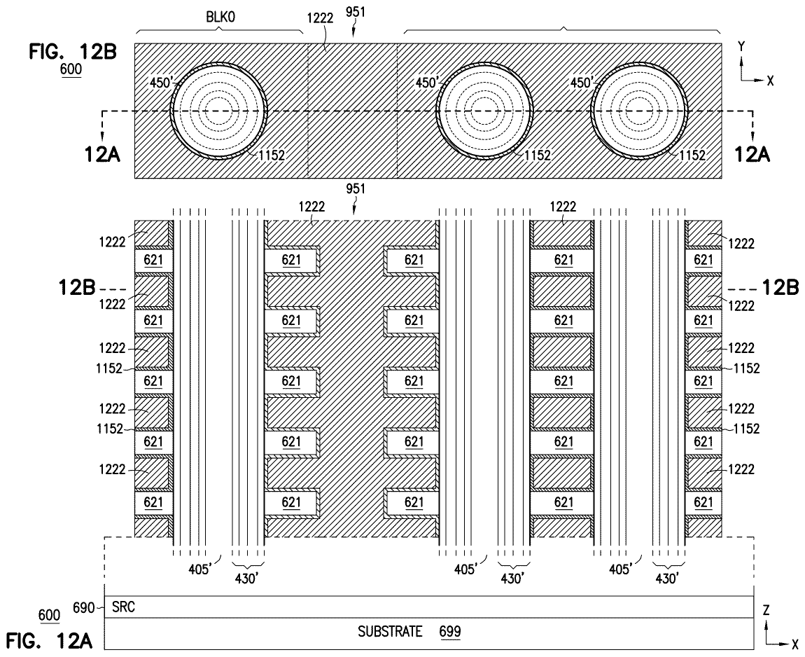

FIG. 10A and FIG. 10B show memory device 600 after dielectric materials 622 are removed (e.g., exhumed) from locations 1022. Locations 1022 in FIG. 10A are voids (empty spaces) that were occupied by dielectric materials 622 in FIG. 9A. In subsequent processes, materials (e.g., dielectric liner 1152 in FIG. 11A and conductive material 1222 in FIG. 12A) can be formed in locations 1022 to form respective control gates of memory device 600. As shown in FIG. 10A, each pillar 450′ can include portions 450′W exposed at respective locations 1022. Each portion 450′W can be part of a vertical sidewall of a respective pillar 450. As shown in FIG. 10A, each portion 450′W can extend in the Z-direction between two adjacent levels of dielectric materials 621 that are also exposed at a respective location 1022.

FIG. 11A and FIG. 11B show memory device 600 after a dielectric liner 1152 is formed. Dielectric liner 1152 can be similar to or the same as dielectric liner 452 of memory device 200 of FIG. 4B. For example, dielectric liner 1152 can include a high-k dielectric material (e.g., AlOx, TiSiN, HfSiOx, HfOx, or other high-k dielectric materials). As shown in FIG. 11A and FIG. 11B, dielectric liner 1152 can be a relatively thin layer (e.g., thin film) that can coat (e.g., can be conformal to) portions 450′W (e.g., sidewalls) of pillars 450′ and portions of dielectric materials 621 that are exposed at locations 1022. Dielectric liner 1152 can also be formed on portions (e.g., vertical sidewalls, not labeled) of dielectric materials 621 that are exposed at slit 951.

FIG. 12A and FIG. 12B show memory device 600 after a conductive material 1222 is formed. Conductive material 1222 can be similar to or the same as conductive material 422 of FIG. 4D and FIG. 4E. Examples of conductive material 1222 include tungsten, molybdenum, or other conductive materials. As shown in FIG. 12A and FIG. 12B, conductive material 1222 can be formed adjacent (e.g., formed on) dielectric liner 1152 and can occupy (e.g., fill) the rest of the voids at locations 1022 (labeled in FIG. 10A and FIG. 10B) and slit 951.

FIG. 13A and FIG. 13B show memory device 600 after formation of a slit 1351 (e.g., an opening, a trench, or a cut), control gates (e.g., control gates associated with signals WL0₀, WL1₀, WL2₀, and WL3₀) of block BLK0, and control gates (e.g., control gates associated with signals WL0₁, WL1₁, WL2₁, and WL3₁) of block BLK1. The control gates of block BLK0 (on respective levels 1310, 1311, 1312, and 1313) and the control gates of block BLK1 (on respective levels 1310, 1311, 1312, and 1313) are similar to (e.g., can correspond to) control gates 220₀, 221₀, 222₀, and 223₀ in block BLK0, and control gates 220, 221₁, 222₁, and 223₁ in block BLK1, respectively, of memory device 200 of FIG. 4A. Levels 1310, 1311, 1312, and 1313 of memory device 600 can be similar to (e.g., can correspond to) levels 410, 411, 412, and 413 of memory device 200 of FIG. 4A.

In FIG. 13A and FIG. 13B, forming the control gates of block BLK0 and the control gates of block BLK1 of memory device 600 can include removing (e.g., by etching or cutting) a portion of conductive material 1222 at the location of slit 1351 (thereby forming slit 1351). The remaining portions of conductive material 1222 at different levels (e.g., tiers) within the same block are separated (electrically separated) from each other. The remaining portions of conductive material 1222 in block BLK0 (which form the control gates of block BLK0) are also separated (electrically separated) from the remaining portions of conductive material 1222 in block BLK1 (which form the control gates of block BLK1).

Thus, as shown in FIG. 13A, forming slit 1351 can divide the levels of dielectric materials 621 and the levels of conductive materials 1222 into a portion (e.g., a portion on the left of slit 1351 in FIG. 13A) of the levels of dielectric materials 621 and the levels of conductive materials 1222 and another portion (e.g., a portion on the right of slit 1351 in FIG. 13A) of the levels of dielectric materials and the levels of conductive materials.

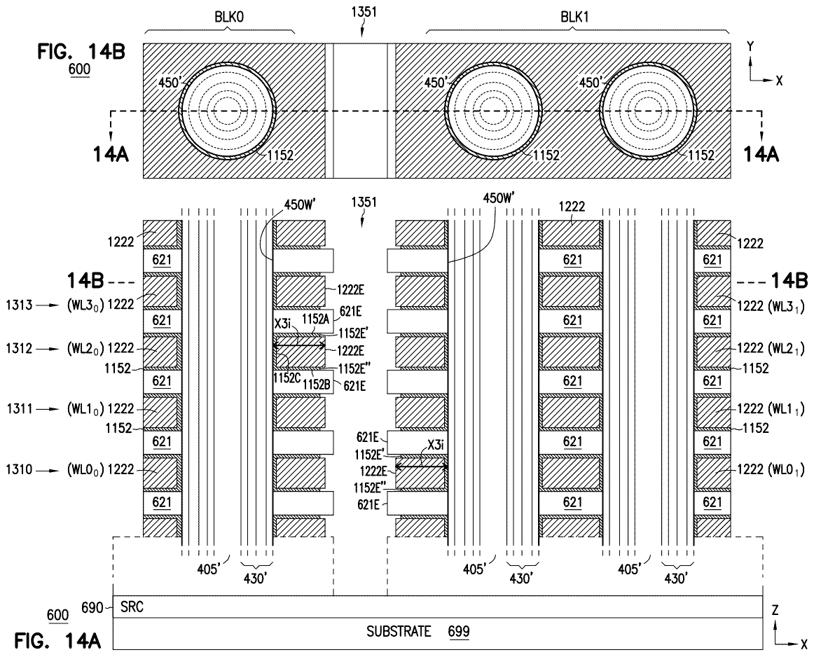

FIG. 14A and FIG. 14B show memory device 600 after a portion of dielectric liner 1152 is removed (e.g., cut). The remaining portion of dielectric liner 1152 form dielectric portions 1152A, 1152B, and 1152C adjacent a respective conductive material 1222. Removing a portion of dielectric liner 1152 can include removing a portion of dielectric liner 1152 from edge 621E of dielectric materials 621, such that edge 621E is exposed at slit 1351. Removing a portion of dielectric liner 1152 can also include removing a portion of dielectric liner 1152 between a level of conductive material 1222 and respective level of dielectric materials 621, thereby forming dielectric portions 1152A having edge 1152E′ and dielectric portions 1152B having edge 1152E″, as shown in FIG. 14A.

As shown in FIG. 14A and FIG. 14B, conductive materials 1222 exposed at slit 1351 can have a dimension corresponding to a distance X3i. Distance X3i can be measured between edge 1222E of a level of conductive material 1222 at slit 1351 and portion 450W′ (e.g., part of a sidewall) of a respective pillar 450.

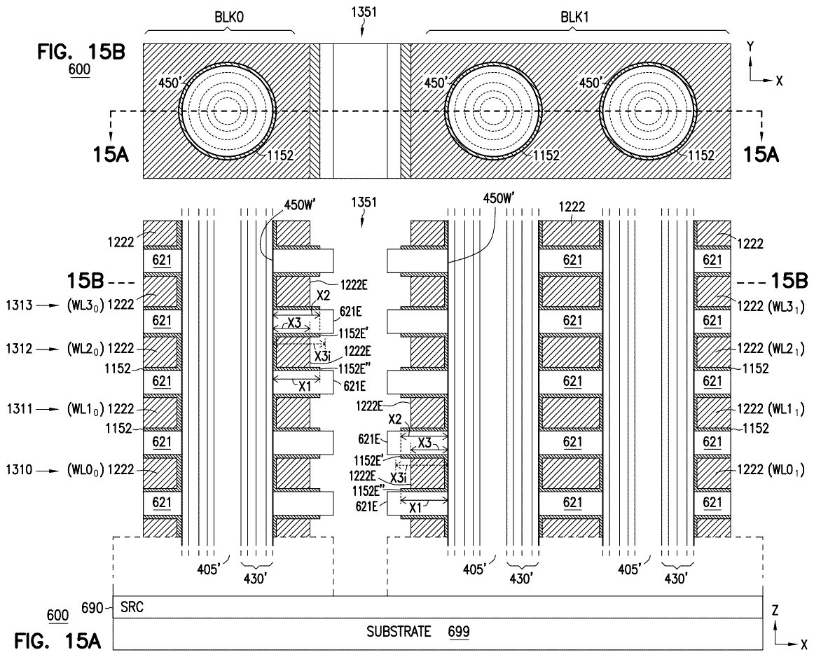

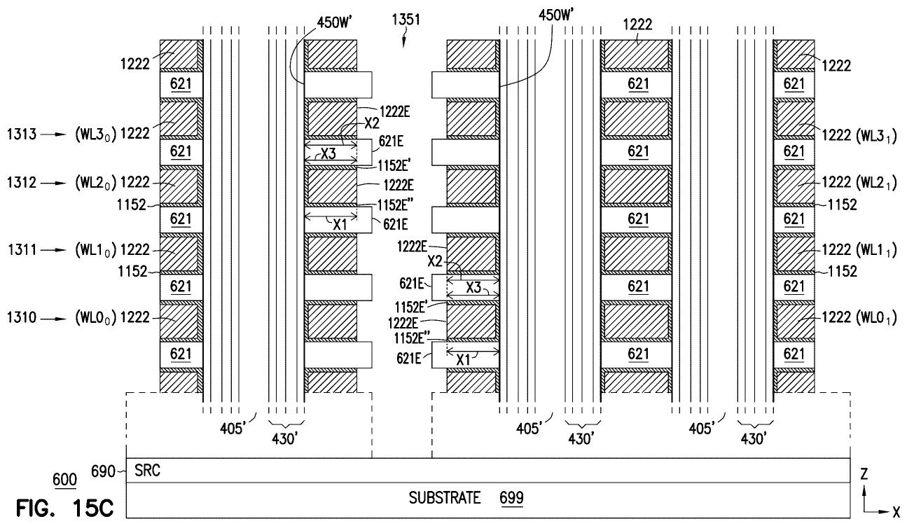

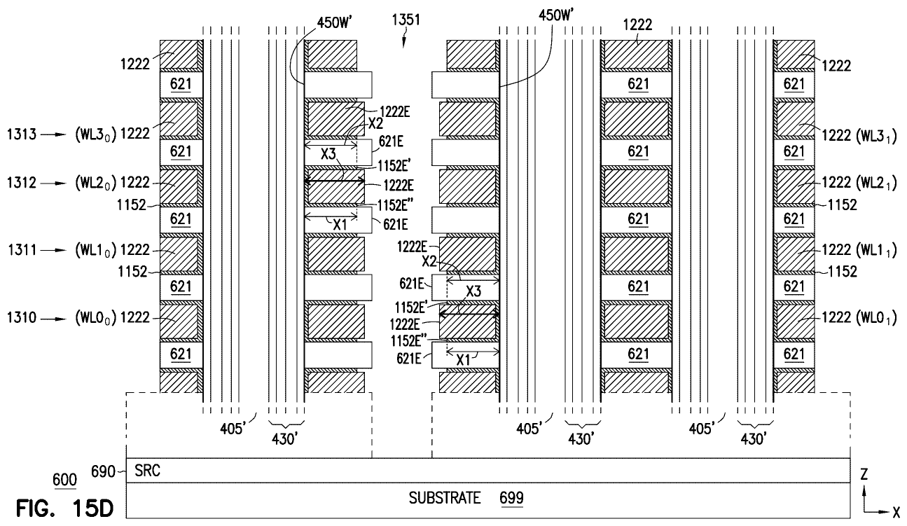

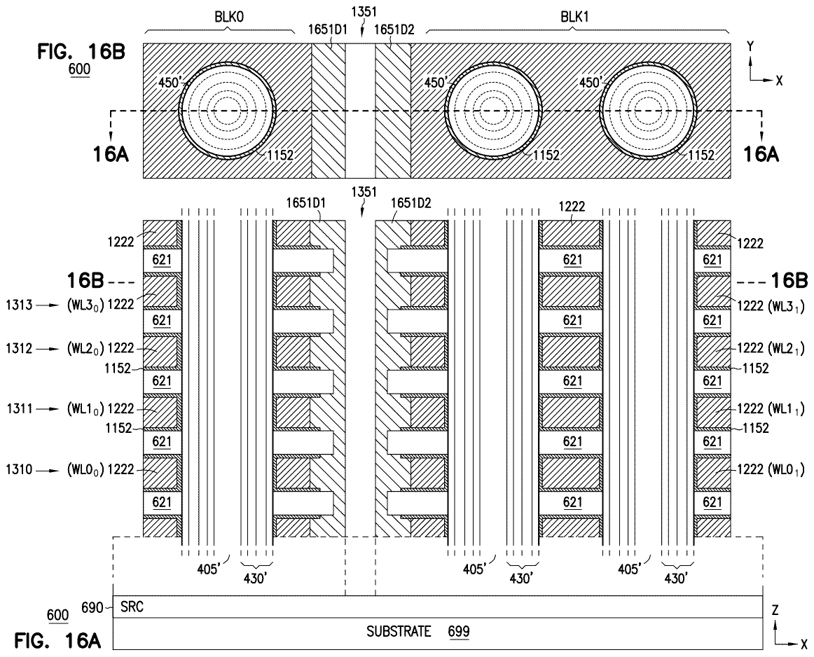

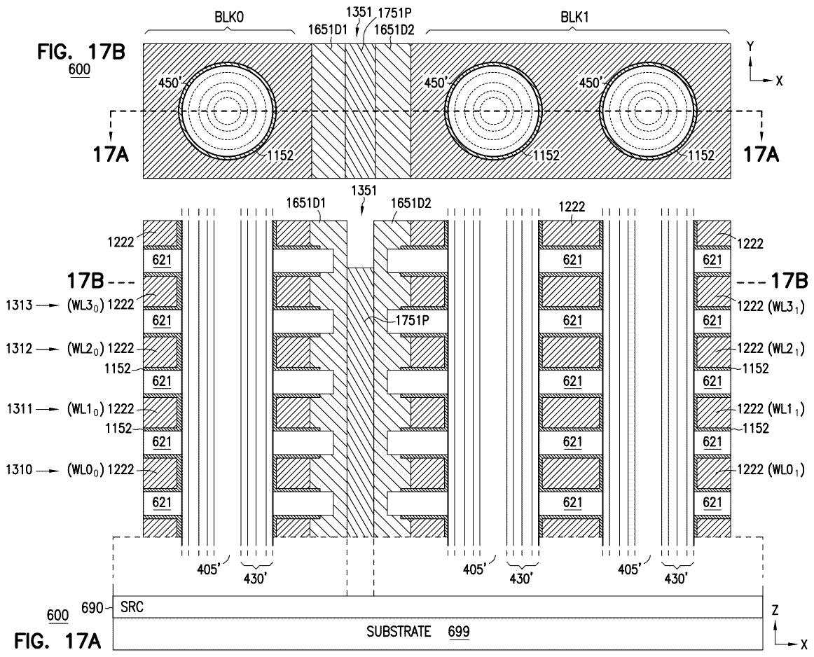

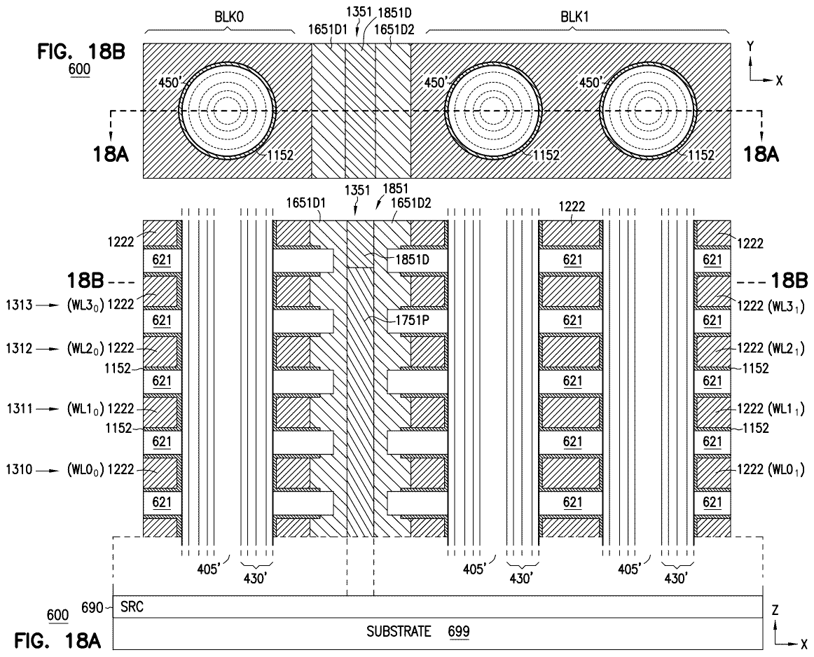

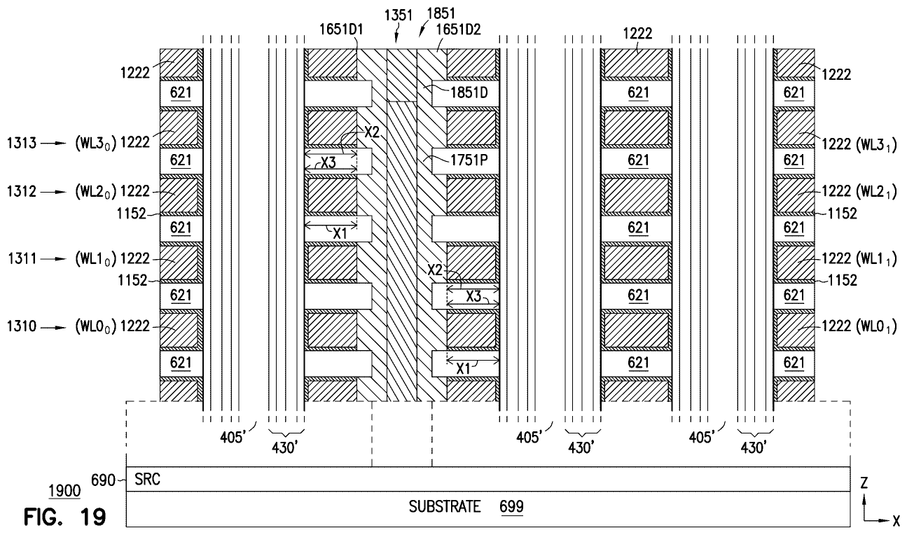

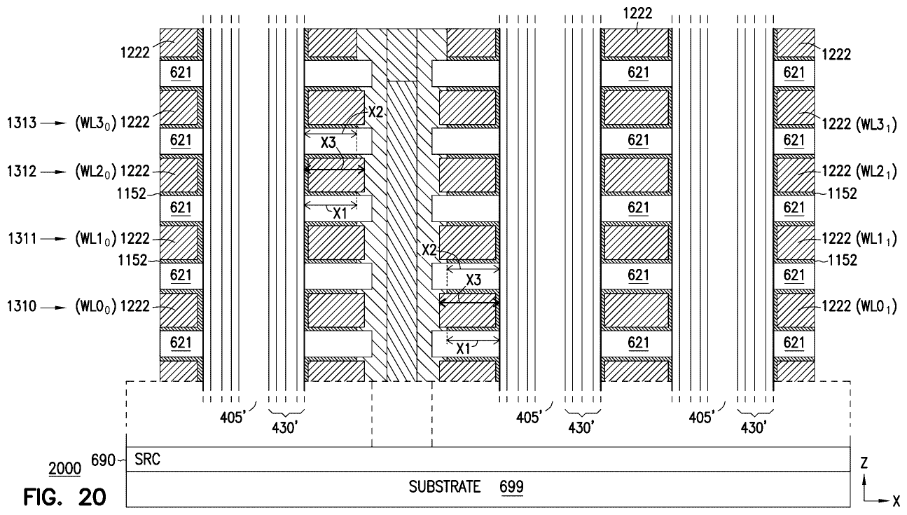

FIG. 15A and FIG. 15B show memory device 600 after an additional portion of conductive materials 1222 at slit 1351 is removed (e.g., recessed) by for example, etching processes or cutting processes. As shown in FIG. 15A, the remaining portion of conductive materials 1222 at slit 1351 can have a dimension corresponding to a distance X3. Distance X3 can be measured between edge 1222E of a respective level of conductive material 1222 at slit 1351 and portion 450W′ (e.g., part of a sidewall) of a respective pillar 450. Distance X3 can be similar to or the same as distance X3 of FIG. 4E.

FIG. 15A also show distances X1 and X2 associated with respective level of conductive materials 1222 at slit 1351. Distances X1 and X2, can be similar to or the same as distances X1 and X2, respectively, of FIG. 4E. As shown in FIG. 4E, distance X1 can be measured from portion 450W′ (e.g., part of a sidewall) of pillar 450′ to edge 1152E′ of dielectric portion 11521A. Distance X2 can be measured from portion 450W′ of pillar 450′ to edge 1152E″ of dielectric portion 451B.

The processes associated with FIG. 15A, the removal of the additional portion of conductive materials 1222 at slit 1351 can be controlled, such that distance X3 can be less than distance X3i (e.g., X3<X3i) and that distance X3 can be less than each of distance X1 and distance X2 (e.g., X3<X1 (or X2)). This also means that distance X1 (or X2) is not less than distance X3. The removal of the additional portion of conductive materials 1222 at slit 1351 can be controlled by ways that can include controlling an etch rate of conductive materials 1222 at slit 1351, or a etch duration (amount of time to etch conductive materials 1222 at slit 1351), or both.

FIG. 15C shows memory device 600 in alternative processes in which the removal of the additional portion of conductive materials 1222 at slit 1351 can be controlled, such that distance X3 can be equal to each of distance X1 and X2 (e.g., X3=X1 (or X2)). Thus, as shown in FIG. 15C, each of edge 1152E′ and 1152E″ is not closer to pillar 450 (in the X-direction) than edge 1222E. This means that from the same reference location (e.g., portion 450W′), each of dielectric portions 452A and 452B can have a dimension (e.g., corresponding to distance X1 or X2) in the x-direction that is the same as (e.g., not longer than) a dimension (e.g., corresponding to distance X3) of a respective level of conductive material 422.

FIG. 15D shows memory device 600 in other alternative processes in which the removal of the additional portion of conductive materials 1222 at slit 1351 can be controlled, such that distance X3 can be greater than each of distance X1 and X2 (e.g., X1 (or X2)<X3). Thus, as shown in FIG. 15D, each of edges 1152E′ and 1152E″is closer to pillar 450 (in the X-direction) than edge 1222E. This also means that from the same reference location (e.g., portion 450W), a respective level of conductive material 422 at slit 1351 can have a dimension (e.g., corresponding to distance X3) in the x-direction that is greater (e.g., longer) than a dimension (e.g., corresponding to distance X1 or X2) of each of dielectric portions 1152A and 1152B adjacent the respective level of conductive material 422 at slit 1351.

The processes of forming memory device 600 can continue from FIG. 15A and FIG. 15B to FIG. 16A and FIG. 16B.

FIG. 16A and FIG. 16B show memory device 600 after dielectric materials 1651D1 and 1651D2 are formed. Forming dielectric materials 1651D1 and 1651D2 can include forming (e.g., depositing) a dielectric material on edges 621E, 1152E′, 1152E″, and 1222E (labeled in FIG. 15A) of respective dielectric materials 622, dielectric liner 1152, and conductive material 1222 that are exposed at slit 1351.

Dielectric materials 1651D1 and 1651D2 are similar to (e.g., can correspond to) dielectric materials 451D1 and 451D2, respectively, of memory device 200 of FIG. 4D. Dielectric liners 451L1 and 451L2 can have the same dielectric material. In an example, each of dielectric materials 1651D1 and 1651D2 can include a dielectric material (e.g., silicon dioxide) that is the same as dielectric materials 621. In another example, each of dielectric materials 1651D1 and 1651D2 can include a dielectric material that is different from dielectric materials 621. In an example, each of dielectric materials 1651D1 and 1651D2 can include silicon nitride.

FIG. 17A and FIG. 17B show memory device 600 after a material 1751P is formed. Material 1751P can be different from dielectric material 1651D1 and 1651D2. Material 1751P can include a semiconductor material. For example, Material 1751P can include polysilicon. As shown in FIG. 17A, forming material 1751P can including forming (e.g., depositing) a material (e.g., semiconductor material) in slit 1351, such that material 1751P can occupy a portion of (e.g., can partially fill) slit 1351.

FIG. 18A and FIG. 18B show memory device 600 after a dielectric material 1851D is formed. Dielectric material 1851D can be similar to (or the same as) dielectric material 451D3 of memory device 200 of FIG. 4D. The material of dielectric material 1851D can be different from (or the same as) dielectric materials 1651D1 and 1651D2. In an example, dielectric material 1851D can include silicon dioxide. As shown in FIG. 18A, forming dielectric material 1851D can including forming (e.g., depositing) a material (e.g., silicon dioxide) over material 1751P in slit 1351, such that dielectric material 1851D can occupy the rest of slit 1351. Thus, as shown in FIG. 18A, a dielectric structure 1851 is formed that includes dielectric materials 1651D1 and 1651D2, material 1651P, and dielectric material 1851D. Dielectric structure 1851 can be similar to (e.g., can correspond to) dielectric structure 451 of memory device 200 of FIG. 4D and FIG. 4E.

FIG. 19 shows a memory device 1900 that can be a variation of memory device 600 of FIG. 18A. As shown in FIG. 19, memory device 1900 includes elements that are similar to or the same as those of memory device 600 of FIG. 18A. Thus, for simplicity, descriptions of similar to the same elements between memory devices 200 and 1900 are not repeated. Memory device 1900 can be formed from the processes associated with FIG. 15C. Thus, as shown in FIG. 19, distance X3 can be equal to each of distance X1 and X2 (e.g., X3=X1 (or X2)), as described above with reference to FIG. 15C.

FIG. 20 shows a memory device 2000 that can be a variation of memory device 600 of FIG. 18A. As shown in FIG. 20, memory device 2000 includes elements that are similar to or the same as those of memory device 600 of FIG. 18A. Thus, for simplicity, descriptions of similar to the same elements between memory devices 200 and 2000 are not repeated. Memory device 2000 can be formed from the processes associated with FIG. 15C. Thus, as shown in FIG. 20, distance X3 can be greater than each of distance X1 and X2 (e.g., X3>X1 (or X2)), as described above with reference to FIG. 15D.

The description of forming memory devices 600, 1900, and 2000 with reference to FIG. 6A and FIG. 6B through FIG. 18A and FIG. 18B, FIG. 19, and FIG. 20 can include other processes to form a complete memory device (e.g., memory device 600). Such processes are omitted from the above description so as not to obscure the subject matter described herein. Memory devices 600, 1900, and 2000 can have improvements and benefits similar to that of memory device 200. For example, the relationships in dimensions (corresponding to distances X1, X2, and X3) between conductive materials 1222 at slit 1351 and dielectric portions 1152A and 1152B as described above can provide similar or the same improvements and benefits like those of memory device 200.

The illustrations of apparatuses (e.g., memory devices 100, 200, 600, 1900, and 2000) and methods (e.g., processes associated with forming memory devices 600, 1900, and 2000) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 600, 1900, and 2000) or a system (e.g., a computer, a cellular phone, or other electronic systems) that includes a device such as any of memory devices 100, 200, 600, 1900, and 2000.

Any of the components described above with reference to FIG. 1 through FIG. 20 can be implemented in a number of ways, including simulation via software. Thus, apparatuses, e.g., memory devices 100, 200, 600, 1900, and 2000, or part of each of these memory devices described above, may all be characterized as “modules” (or “module”) herein. Such modules may include hardware circuitry, single-and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 600, 1900, and 2000 may be included in apparatuses (e.g., electronic circuitry) such as high-speed computers, communication and signal processing circuitry, single-or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 20 include apparatuses, and methods of forming the apparatuses. One of the apparatuses includes a dielectric liner including a first dielectric portion between a level of conductive material and a first level of dielectric material and, and a second dielectric portion between the level of conductive material and a second level of dielectric material; a memory cell pillar extending through the first level of dielectric material and the second level of dielectric material; and a dielectric structure adjacent the first level of dielectric material, the second level of dielectric material, and the dielectric liner. The first dielectric portion includes first and second edges adjacent the dielectric structure. The level of conductive material includes a third edge adjacent the dielectric structure. The third edge is closer to the memory cell pillar than each of the first edge and the second edge.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first level of dielectric material;
a second level of dielectric material;
a level of conductive material between the first level of dielectric material and second level of dielectric material;
a dielectric liner including a first dielectric portion between the level of conductive material and the first level of dielectric material and, and a second dielectric portion between the level of conductive material and the second level of dielectric material;
a memory cell pillar extending through the first level of dielectric material and the second level of dielectric material; and
a dielectric structure adjacent the first level of dielectric material, the second level of dielectric material, and the dielectric liner, wherein:
the first dielectric portion includes a first edge adjacent the dielectric structure;
the second dielectric portion includes a second edge adjacent the dielectric structure;
the level of conductive material includes a third edge adjacent the dielectric structure; and
the third edge is closer to the memory cell pillar than each of the first edge and the second edge.

2. The apparatus of claim 1, wherein the dielectric liner has a dielectric constant greater than a dielectric constant of silicon dioxide.

3. The apparatus of claim 1, wherein the dielectric liner includes aluminum oxide.

4. The apparatus of claim 1, wherein the level of conductive material includes molybdenum.

5. The apparatus of claim 1, wherein:
the first dielectric portion includes a first thickness;
the second dielectric portion includes a second thickness; and
the level of conductive material includes a third thickness, and the third thickness is greater than each of the first thickness and the second thickness.

6. The apparatus of claim 1, wherein the dielectric liner includes:
a third dielectric portion coupled to the first portion and the second portion; and
the level conductive material is adjacent the first dielectric portion, the second dielectric portion, and the third dielectric portion.

7. The apparatus of claim 1, wherein the dielectric structure includes a dielectric material adjacent the first edge, the second edge, and the third edge, and the dielectric material is different from the first level of dielectric material and the second level of dielectric material.

8. The apparatus of claim 1, wherein the dielectric structure includes a dielectric material adjacent the first edge, the second edge, and the third edge, and the dielectric material is a same as the first level of dielectric material and the second level of dielectric material.

9. The apparatus of claim 1, wherein the dielectric structure includes:
a dielectric material adjacent the first edge, the second edge, and the third edge; and
a semiconductor adjacent the dielectric material.

10. The apparatus of claim 9, wherein the semiconductor includes polysilicon.

11. An apparatus comprising:
levels of first control gates interleaved with levels of first dielectric materials, at least one of the levels of first control gates including a level of conductive material and a dielectric liner;
levels of second control gates interleaved with levels of second dielectric materials;
a dielectric structure separating the levels of first control gates and the levels of first dielectric materials from the levels of second control gates and the levels of second dielectric materials; and
a memory cell pillar extending through the levels of first control gates and the levels of first dielectric materials, wherein:
the conductive material includes a first edge adjacent the dielectric structure, the first edge located at a first distance from the memory cell pillar; and
the dielectric liner includes a dielectric portion including a second edge adjacent the dielectric structure, the second edge located at a second distance from the memory cell pillar, wherein the first distance is not greater than the second distance.

12. The apparatus of claim 11, further comprising:
an additional memory cell pillar extending through the levels of second control gates and the levels of second dielectric materials, wherein:
at least one of the levels of second control gates including an additional conductive material and an additional dielectric liner;
the additional conductive material includes a first additional edge adjacent the dielectric structure, the first additional edge located at a first additional distance from the additional memory cell pillar; and
the additional dielectric liner includes a second additional edge adjacent the dielectric structure, the second additional edge located at a second additional distance from the additional memory cell pillar, wherein the first additional distance is not greater than the second additional distance.

13. The apparatus of claim 11, wherein the dielectric liner has a dielectric constant greater than a dielectric constant of silicon dioxide.

14. The apparatus of claim 11, wherein the dielectric portion is a first portion, and wherein:
the dielectric liner includes a second dielectric portion, the level of conductive material is between the first dielectric portion and the second dielectric portion; and
the second dielectric portion includes a third edge adjacent the dielectric structure, the third edge located at a third distance from the memory cell pillar, wherein the third distance is greater than the first distance.

15. The apparatus of claim 14, wherein the dielectric liner includes:
a third dielectric portion coupled to the first portion and the second portion; and
the conductive material is adjacent the first portion, the second portion, and the third portion.

16. The apparatus of claim 11, wherein the apparatus comprises a memory device, the memory device including a first memory cell block and a second memory cell block, and wherein:
the levels of first control gates and the levels of first dielectric materials are included in the first memory cell block; and
the levels of second control gates and the levels of second dielectric materials are included in the second memory cell block.

17. The apparatus of claim 11, wherein the dielectric structure includes silicon nitride adjacent the first edge and the second edge.

18. A method of forming a memory device, comprising:
forming levels of dielectric materials;
forming levels of conductive materials interleaved with the levels of dielectric materials;
forming a memory cell pillar through the levels of dielectric materials levels and the levels of conductive materials;
forming a dielectric liner before forming levels of conductive materials, such that each of the levels of conductive materials is separated from the levels of dielectric materials by respective dielectric portions of the dielectric liner;
forming a slit through the levels of conductive materials and the levels of dielectric materials to expose the levels of conductive materials at the slit;
removing a first portion of the levels of conductive materials exposed at the slit to expose the dielectric liner at the slit;
removing a portion of the dielectric liner, such that remaining dielectric portions of the dielectric liner include first edges exposed at the slit, each of the first edges located at a first distance from the memory cell pillar;
removing a second portion of the level of conductive materials exposed at the slit, such a remaining portion of the levels of conductive materials include second edges exposed at the slit, each of the second edges located at a second distance from the memory cell pillar, wherein the first distance is not less than the second distance; and
forming a dielectric structure in the slit.

19. The method of claim 18, wherein the dielectric liner has a dielectric constant greater than a dielectric constant of silicon dioxide.

20. The method of claim 18, wherein the levels of conductive materials are part of control gates of memory cells associated with the memory cell pillar.
